(19) United States
(12) Patent Application Publication
(10) Pub. No.: US 2025/0204235 A1
(43) Pub. Date: Jun. 19, 2025

(54) A TRANSFERRABLE PHOTOVOLTAIC DEVICE

(71) Applicant: COMMONWEALTH SCIENTIFIC AND INDUSTRIAL RESEARCH ORGANISATION, Acton, Australian Capital Territory (AU)

(72) Inventors: Doojin VAK, Clayton, Victoria (AU); Hasitha WEERASINGHE, Clayton, Victoria (AU); Luke SUTHERLAND, Clayton, Victoria (AU); Mei GAO, Clayton, Victoria (AU)

(21) Appl. No.: 18/847,649

(22) PCT Filed: Mar. 16, 2023
(86) PCT No.: PCT/AU2023/050184

§ 371 Date: Sep. 16, 2024

(30) Foreign Application Priority Data
Mar. 17, 2022 (AU) 2022900663

(51) Int. Cl. H10K 71/80; H10K 30/57; H10K 39/15; H10K 39/18; H10K 71/50; H10K 71/60; H10K 85/50

(52) U.S. Cl. CPC H10K 71/80; H10K 30/57; H10K 39/15; H10K 39/18; H10K 71/50; H10K 71/60; H10K 85/50

(57) ABSTRACT

The invention provides a transferrable photovoltaic device arrangement for transferring a thin-film photovoltaic device to a bottom photovoltaic sub-cell to produce a tandem photovoltaic cell, the transferrable photovoltaic device arrangement comprising: a flexible release substrate; and a thin-film photovoltaic device comprising (i) a first transparent conductive layer located over the flexible release substrate and (ii) a photoactive layer located over the first transparent conductive layer, wherein the first transparent conductive layer is a solution-processed layer comprising at least one selected from a conductive polymer or polymer composite, an activatable adhesive, and an organic binder, and wherein the flexible release substrate is separable from the thin-film photovoltaic device after the thin-film photovoltaic device is adhered to the bottom photovoltaic sub-cell with a transparent conductive adhesive, thereby exposing the first transparent conductive layer at an outer conductive surface of the thin-film photovoltaic device.

### PRIORITY CROSS-REFERENCE

The present application claims priority from Australian Provisional Patent Application No. 2022900663 filed on 17 Mar. 2022, the contents of which should be understood to be incorporated into the present specification by this reference.

### TECHNICAL FIELD

The present invention relates to a transferrable photovoltaic device arrangement for transferring a thin-film photovoltaic device to a bottom photovoltaic sub-cell to produce a tandem photovoltaic cell. The transferrable photovoltaic device arrangement comprises a flexible release substrate and a thin-film photovoltaic device thereon, the flexible release substrate being separable from the thin-film photovoltaic device after the thin-film photovoltaic device is adhered to a bottom photovoltaic sub-cell with a transparent conductive adhesive. The invention also relates to a method of producing a transferrable photovoltaic device arrangement, and to a method of producing a tandem photovoltaic cell using a transferrable photovoltaic device arrangement.

### BACKGROUND OF INVENTION

Silicon-based photovoltaic (PV) cells are by far the dominant photovoltaic technology presently used in commercial solar panels. The cost of electricity from such solar panels has dropped enormously in recent decades due to improved power conversion efficiencies and the benefits of manufacturing both the inputs and the final solar panel modules on a large scale. However, single-junction PV cells, which include a single photoactive layer interposed between one pair of charge collecting electrodes, have an intrinsic efficiency limitation due to various mechanisms including the low bandgap spectrum loss and the energy loss (thermalisation) by relaxation to the band edges. The power conversion efficiency of state-of-the-art solar panels utilizing single-junction Si-PV cells (<27%) is now approaching the maximum that can be expected, and fundamental changes to the photovoltaic cell technology are thus needed to provide substantial further improvements.

One approach to improve the power conversion efficiency of solar panels is to utilize a multijunction PV cell, in which two (or more) PV sub-cells are physically stacked on top of each other. The photoactive layer of the top sub-cell is designed to efficiently absorb photons from a high energy region of the solar irradiance spectrum, with the photoactive layer of the bottom sub-cell capturing lower energy photons which pass through the semi-transparent top sub-cell. Tandem PV cells, in which the two sub-cells are electrically connected in series via a transparent conductive interlayer (the recombination layer or tunnel junction), can thus achieve a power conversion efficiency of up to 47% under concentrated sunlight. Therefore, in principle, tandem PV cells having a Si-PV bottom sub-cell could provide substantially improved power conversion efficiencies over single-junction Si-PV cells while still benefiting from modern Si-PV manufacturing techniques.

Despite these theoretical advantages, the development of commercially competitive multijunction PV cells, and particularly those with Si-PV bottom sub-cells, is challenging due to technical and cost-related issues with the fabrication of the top sub-cell and its integration with the bottom sub-cell. Vapor deposition methods for fabrication of a top sub-cell on a Si-PV bottom sub-cell are not readily amendable to industrial scale-up. Thin-film top sub-cells which include a solution-processable photoactive layer, such as a metal halide perovskite semiconductor, are particularly attractive due to the capability to tailor the bandgap appropriately. However, layer-by-layer fabrication of a top sub-cell directly on a Si-PV bottom sub-cell by solution-processing methods remains technically and economically demanding due to the difficulty of forming a uniformly thin layer on a large-area rigid substrate and the large fraction of material wastage of batch-processed deposition methods.

It has previously been proposed to address these issues by producing the thin-film top sub-cell separately and then laminating this multi-layered device directly to the bottom sub-cell to produce a tandem PV cell in a single process step. A transparent conductive adhesive is used to physically adhere the two devices and to provide the required electrical interconnection (as the recombination layer or tunnel junction) between the two sub-cells in the final tandem PV cell. However, thin-film devices are not self-supporting and the thin-film top sub-cell must therefore be fabricated on a supportive film substrate. This substrate will then form a relatively thick outer layer of the tandem PV cell after laminating the top and bottom sub-cells together, which can potentially absorb a non-negligible portion of the solar radiation and thus adversely affect the power conversion efficiency. Furthermore, supportive film substrates on which thin-film electronic devices are produced are typically electrically insulating. While an insulating outer layer can be accommodated in small-scale devices, it is undesirable on larger surface area photovoltaic cells where the current is typically withdrawn through the outer surface to minimise internal resistance in the solar panel.

Other reported approaches for manufacturing a top sub-cell, for subsequent lamination to the bottom sub-cell, rely on vapour or plasma deposition techniques and/or high temperature processing steps to produce the thin-film device architecture. The top sub-cell must therefore be produced on a support substrate capable of withstanding such processing conditions, which compromises the transferability of the sub-cell onto a bottom sub-cell when manufacturing a tandem PV cell. It is desirable that a thin-film top sub-cell is produced by low cost and scalable techniques directly on a substrate suitable for transfer to the bottom sub-cell.

Therefore, there is an ongoing need for methods of producing a tandem photovoltaic cell, and arrangements for transferring a thin-film photovoltaic device to a bottom sub-cell to form a tandem photovoltaic cell, which at least partially address one or more of the above-mentioned short-comings, or provide a useful alternative.

A reference herein to a patent document or other matter which is given as prior art is not to be taken as an admission that the document or matter was known or that the information it contains was part of the common general knowledge as at the priority date of any of the claims.

### SUMMARY OF INVENTION

The inventors have now developed a method of producing a tandem photovoltaic cell by transferring a thin-film photovoltaic top sub-cell, initially present on a supportive release substrate, to a compatible bottom sub-cell and thereafter removing the release substrate to provide a tandem PV cell with a transparent conductive layer at the outer surface. The transparent conductive layer is produced on the release substrate by solution-processing and comprises organic and typically polymeric conductive and/or binder components, yet the interface between the release substrate and the transparent conductive layer is engineered to allow selective delamination of the release substrate from the top sub-cell after the top and bottom sub-cells are adhered, leaving the transparent conductive layer exposed at a conductive outer surface of the tandem PV cell. This can be achieved in several ways, for example by designing the release substrate for intrinsically weak adhesion to the transparent conductive layer or by formulating the transparent conductive layer to de-bond from the release substrate in response to an external stimulus.

The presence of organic or polymeric components in the first transparent conductive layer is expected to improve its flexibility and resilience, ensuring that the physical integrity and conductivity of the first transparent conductive layer persists despite flexing and compression applied to the layer during transfer of the thin-film photovoltaic device to a bottom photovoltaic sub-cell.

The thin-film top sub-cell is adhered to the bottom sub-cell via a transparent conductive adhesive layer, which ultimately forms the recombination layer (also known as a tunnel junction) in the tandem photovoltaic device. The transparent conductive adhesive layer, which in some embodiments is present initially as an outer layer of the transferrable top sub-cell, may be activated and optionally cured to facilitate adhesion of the two sub-cells. Importantly, the resultant adhesive bond between the two sub-cells is stronger than the bond between the release substrate and the top sub-cell when the release substrate is to be separated from the thin-film top sub-cell.

Advantageously, the methods and devices disclosed herein can be used to produce tandem photovoltaic cells with silicon-based photovoltaic (Si-PV) cells and are compatible with both manufacturing processes for Si-PV cells and common uses of Si-PV cells in solar panel modules. Thus, the thin-film top sub-cell may be pressed onto and adhered to a bottom sub-cell (e.g. a Si-PV sub-cell) in a roll lamination process which includes near-simultaneous separation and removal of the release substrate. Furthermore, because the resultant tandem photovoltaic cell has a conductive outer surface, this outer surface can be further functionalised with a current collector network, e.g. a printed metallic grid, as typically applied to Si-PV cells.

In a first aspect, the invention provides a transferrable photovoltaic device arrangement for transferring a thin-film photovoltaic device to a bottom photovoltaic sub-cell to produce a tandem photovoltaic cell, the transferrable photovoltaic device arrangement comprising: a flexible release substrate; and a thin-film photovoltaic device comprising (i) a first transparent conductive layer located over the flexible release substrate and (ii) a photoactive layer located over the first transparent conductive layer, wherein the first transparent conductive layer is a solution-processed layer comprising at least one selected from a conductive polymer or polymer composite, an activatable adhesive, and an organic binder, and wherein the flexible release substrate is separable from the thin-film photovoltaic device after the thin-film photovoltaic device is adhered to the bottom photovoltaic sub-cell with a transparent conductive adhesive, thereby exposing the first transparent conductive layer at an outer conductive surface of the thin-film photovoltaic device.

In some embodiments, the first transparent conductive layer comprises a first activatable adhesive, wherein the flexible release substrate is separable from the thin-film photovoltaic device when the first activatable adhesive is activated. The first activatable adhesive may be a heat-activatable adhesive polymer. The heat-activatable adhesive polymer may be a thermoplastic polymer, for example selected from the group consisting of an ethylene-vinyl acetate (EVA) copolymer, a polyethylene, a polyethyleneoxide (PEO) and a polystyrene (PS).

In some embodiments, the flexible release substrate comprises a non-stick surface, wherein the flexible release substrate is separable from the thin-film photovoltaic device by delaminating the first transparent conductive layer from the non-stick surface. The non-stick surface may be provided by a low surface energy polymer. The non-stick surface may be a surface of a non-stick coating on the flexible release substrate. The non-stick coating may comprise a low surface energy polymer, for example selected from the group consisting of a fluorinated polymer and a silicone polymer.

In some embodiments, the transferrable photovoltaic device arrangement comprises a low-cohesion sacrificial layer interposed between the flexible release substrate and the first transparent conductive layer, wherein the low-cohesion sacrificial layer has intrinsically low cohesion or has low cohesion when activated such that the flexible release substrate is separable from the thin-film photovoltaic device by breaking the low-cohesion sacrificial layer.

In some embodiments, the low-cohesion sacrificial layer comprises a low-cohesion organic non-polymeric solid. In some embodiments, the low-cohesion sacrificial layer comprises a third activatable adhesive and the flexible release substrate is separable from the thin-film photovoltaic device by (i) activating the third activatable adhesive by heat or radiation and (ii) breaking the low-cohesion sacrificial layer. The third activatable adhesive may be a thermoplastic polymer, for example selected from the group consisting of an ethylene-vinyl acetate (EVA) copolymer, a polyethylene, a polyethyleneoxide (PEO) and a polystyrene (PS), or a light-depolymerizable polymeric composition, for example selected from the group consisting of poly(phthalaldehyde) (PPHA) combined with photo acid generator (PAG), poly(acetal)s combined with PAG and polylactide (PLA) combined with TiO₂.

In some embodiments, the low-cohesion sacrificial layer is conductive. In some embodiments, the low-cohesion sacrificial layer has a thickness of less than 100 nm, or less than 50 nm, or less than 20 nm.

In some embodiments, the first transparent conductive layer comprises a first conductive component selected from the group consisting of a metal, a metal oxide, a conductive polymer or polymer composite, a fullerene or functionalised derivative thereof, a carbon nanomaterial (such as graphene), a non-polymeric organic semiconductor, an organic aromatic compound and a non-polymeric conjugated organic compound.

In some embodiments, the thin-film photovoltaic device further comprises (iii) a second transparent conductive layer, located over the photoactive layer, wherein the second transparent conductive layer comprises the transparent conductive adhesive for adhering the thin-film photovoltaic device to the bottom photovoltaic sub-cell.

In some embodiments, the transparent conductive adhesive comprises a second conductive component comprising at least one selected from the group consisting of a metal, a metal oxide, a conductive polymer or polymer composite, a fullerene or functionalised derivative thereof, a carbon nanomaterial (such as graphene), a non-polymeric organic semiconductor, an organic aromatic compound and a non-polymeric conjugated organic compound.

In some embodiments, the transparent conductive adhesive comprises a second activatable adhesive, wherein the second transparent conductive layer is adherent to the bottom photovoltaic sub-cell when the second activatable adhesive is activated. The second activatable adhesive may be activatable by heat, radiation or chemical treatment. In some embodiments, the second activatable adhesive cures irreversibly by covalent bond forming reactions when activated.

In some embodiments, the transparent conductive adhesive is heat-activatable at a temperature sufficient to release the flexible release substrate from the thin-film photovoltaic device.

In some embodiments, the first transparent conductive layer comprises a first heat-activatable adhesive polymer and the second transparent conductive layer comprises a second heat-activatable adhesive polymer, wherein the second heat-activatable adhesive polymer has a higher melting point than the first heat-activatable adhesive polymer.

In some embodiments, the thin-film photovoltaic device further comprises (iv) a first charge transport layer interposed between the first transparent conductive layer and the photoactive layer and/or (v) a second charge transport layer located over the photoactive layer.

In some embodiments, the photoactive layer is a photoactive perovskite layer.

In some embodiments, the transferrable photovoltaic device arrangement is configured as a roll for a roll lamination process in which the thin-film photovoltaic device is pressed onto the bottom photovoltaic sub-cell and the flexible release substrate is separated from the thin-film photovoltaic device.

In some embodiments, each functional layer of the thin-film photovoltaic device selected from (i) the first transparent conductive layer, (ii) the photoactive layer, (iv) a first charge transport layer interposed between the first transparent conductive layer and the photoactive layer and (v) a second charge transport layer located over the photoactive layer, is a solution-processed layer formed on the flexible release substrate. In some embodiments, each functional layer of the thin-film photovoltaic device is a solution-processed layer formed on the flexible release substrate.

In a second aspect, the invention provides a tandem photovoltaic cell arrangement comprising a bottom photovoltaic sub-cell and a transferrable photovoltaic device arrangement according to any embodiment of the first aspect, wherein the thin-film photovoltaic device is adhered to the bottom photovoltaic sub-cell via a second transparent conductive layer comprising a transparent conductive adhesive.

In some embodiments, the bottom photovoltaic sub-cell is a silicon photovoltaic cell.

In some embodiments, the flexible release substrate is partially separated from the thin-film photovoltaic device, thereby exposing the first transparent conductive layer at an outer conductive surface.

In a third aspect, the invention provides a method of producing a transferrable photovoltaic device arrangement, the method comprising: providing a flexible release substrate; and producing a thin-film photovoltaic device on the flexible release substrate by successively forming (i) a first transparent conductive layer over the flexible release substrate; and (ii) a photoactive layer over the first transparent conductive layer, wherein the first transparent conductive layer is formed by solution-processing and comprises at least one selected from a conductive polymer or polymer composite, an activatable adhesive, and an organic binder, and wherein the flexible release substrate is separable from the thin-film photovoltaic device to expose the first transparent conductive layer at an outer conductive surface of the thin-film photovoltaic device.

In some embodiments, forming the first transparent conductive layer over the flexible release substrate comprises applying a first fluid composition, comprising a first conductive component or reactive precursor thereof, to form a wet film over the flexible release substrate; and solidifying the wet film to form the first transparent conductive layer over the flexible release substrate.

In some embodiments, the first fluid composition further comprises a solvent, and solidifying the wet film comprises removing the solvent.

In some embodiments, the first fluid composition comprises a first activatable adhesive. The first activatable adhesive may be a heat-activatable adhesive polymer, wherein the flexible release substrate is separable from the thin-film photovoltaic device when the first transparent conductive layer is heated.

In some embodiments, the flexible release substrate comprises a non-stick surface and the first transparent conductive layer is formed directly on the non-stick surface.

In some embodiments, the flexible release substrate comprises a low-cohesion sacrificial layer on its surface and the first transparent conductive layer is formed directly on the low-cohesion sacrificial layer.

In some embodiments, forming a photoactive layer over the first transparent conductive layer comprises applying a flowable composition, comprising one or more photoactive layer components or precursors thereof dispersed in a solvent, to form a wet film over the first transparent conductive layer; and forming the photoactive layer by removing the solvent from the wet film. Optionally, the flowable composition is a perovskite precursor solution.

In some embodiments, producing the thin-film photovoltaic device on the flexible release substrate further comprises forming (iii) a second transparent conductive layer, over the photoactive layer, wherein the second transparent conductive layer comprises a transparent conductive adhesive for adhering the thin-film photovoltaic device to a bottom photovoltaic sub-cell. Forming the second transparent conductive layer may comprise applying a second fluid composition, comprising a second activatable adhesive and a second conductive component or reactive precursor thereof, to form a wet film over the photoactive layer; and solidifying the wet film to form the second transparent conductive layer.

In some embodiments, producing the thin-film photovoltaic device on the flexible release substrate further comprises forming (iv) a first charge transport layer interposed between the first transparent conductive layer and the photoactive layer and/or (v) a second charge transport layer over the photoactive layer.

In some embodiments, the flexible release substrate is configured as a roll and the thin-film photovoltaic device is produced on the flexible release substrate by coating and/or printing steps in a roll-to-roll process.

In a fourth aspect, the invention provides a method of producing a tandem photovoltaic cell, comprising: providing a transferrable photovoltaic device arrangement according to any embodiment of the first aspect, or as produced by a method according to any embodiment of the third aspect; adhering the thin-film photovoltaic device of the transferrable photovoltaic device arrangement to a bottom photovoltaic sub-cell with a transparent conductive adhesive, thereby electrically coupling the thin-film photovoltaic device and the bottom photovoltaic sub-cell via a second transparent conductive layer; and separating the flexible release substrate of the transferrable photovoltaic device arrangement from the thin-film photovoltaic device, thereby producing a tandem photovoltaic cell having the first transparent conductive layer of the thin-film photovoltaic device at an outer conductive surface.

In some embodiments, the bottom photovoltaic sub-cell is a silicon photovoltaic cell.

In some embodiments, the thin-film photovoltaic device is pressed or compressed onto the bottom photovoltaic sub-cell to facilitate adhesion before separating the flexible release substrate from the thin-film photovoltaic device.

In some embodiments, the transferrable photovoltaic device arrangement is configured as a roll, and the thin-film photovoltaic device is adhered to the bottom photovoltaic sub-cell and the flexible release substrate is separated from the thin-film photovoltaic device in a roll lamination process.

In some embodiments, adhering the thin-film photovoltaic device to the bottom photovoltaic sub-cell comprises activating the transparent conductive adhesive with heat, radiation or chemical treatment.

In some embodiments, adhering the thin-film photovoltaic device to the bottom photovoltaic sub-cell comprises activating the transparent conductive adhesive with heat at a temperature sufficient to release the flexible release substrate from the thin-film photovoltaic device.

In some embodiments, the method further comprises producing a metallic current collector network on the outer conductive surface of the tandem photovoltaic cell.

According to a fifth aspect, the invention provides a tandem photovoltaic cell produced by a method according to any embodiment of the fourth aspect.

Further aspects of the invention appear below in the detailed description of the invention.

### BRIEF DESCRIPTION OF DRAWINGS

Embodiments of the invention will herein be illustrated by way of example only with reference to the accompanying drawings in which:

FIG. 1 schematically depicts a transferrable photovoltaic device arrangement 100 according to the invention, and a method 150 of producing a tandem photovoltaic cell 130 using this transferrable photovoltaic device arrangement, by transferring photovoltaic device 104 to bottom photovoltaic sub-cell 112.

FIG. 2 schematically depicts a transferrable photovoltaic device arrangement 200 according to embodiments of the invention, and a method 250 of producing a tandem photovoltaic cell 230 using this transferrable photovoltaic device arrangement, by transferring photovoltaic device 204 to bottom photovoltaic sub-cell 212.

FIG. 3 schematically depicts a transferrable photovoltaic device arrangement 300 according to embodiments of the invention, and a method 350 of producing a tandem photovoltaic cell 330 using this transferrable photovoltaic device arrangement, by transferring photovoltaic device 304 to bottom photovoltaic sub-cell 312.

FIG. 4 schematically depicts a transferrable photovoltaic device arrangement 400 according to embodiments of the invention, and a method 450 of producing a tandem photovoltaic cell 430 using this transferrable photovoltaic device arrangement, by transferring photovoltaic device 404 to bottom photovoltaic sub-cell 412.

FIG. 5 is a block flow diagram which shows the steps of a method for producing a transferrable photovoltaic device arrangement according to the invention.

FIG. 6 schematically depicts a method of producing a tandem photovoltaic cell in a roll lamination process according to embodiments of the invention.

FIG. 7 schematically depicts a method of transferring a solution-processed thin-film photovoltaic device from a flexible release substrate to a conductive substrate, as performed in Example 3.

### DETAILED DESCRIPTION

The present invention relates to a transferrable photovoltaic device arrangement for transferring a thin-film photovoltaic device to a bottom photovoltaic sub-cell to produce a tandem photovoltaic cell. The transferrable photovoltaic device arrangement comprises a flexible release substrate and a thin-film photovoltaic device on the flexible release substrate. The thin-film photovoltaic device comprises at least a first transparent conductive layer located over the flexible release substrate and a photoactive layer located over the first transparent conductive layer. The first transparent conductive layer is a solution-processed layer, and comprises at least one selected from a conductive polymer or polymer composite, an activatable adhesive, and an organic binder. In use, the flexible release substrate is separable from the thin-film photovoltaic device after the thin-film photovoltaic device is adhered to a bottom photovoltaic sub-cell with a transparent conductive adhesive. The resultant tandem photovoltaic cell thus has the first transparent conductive layer of the thin-film photovoltaic device exposed at an outer conductive surface.

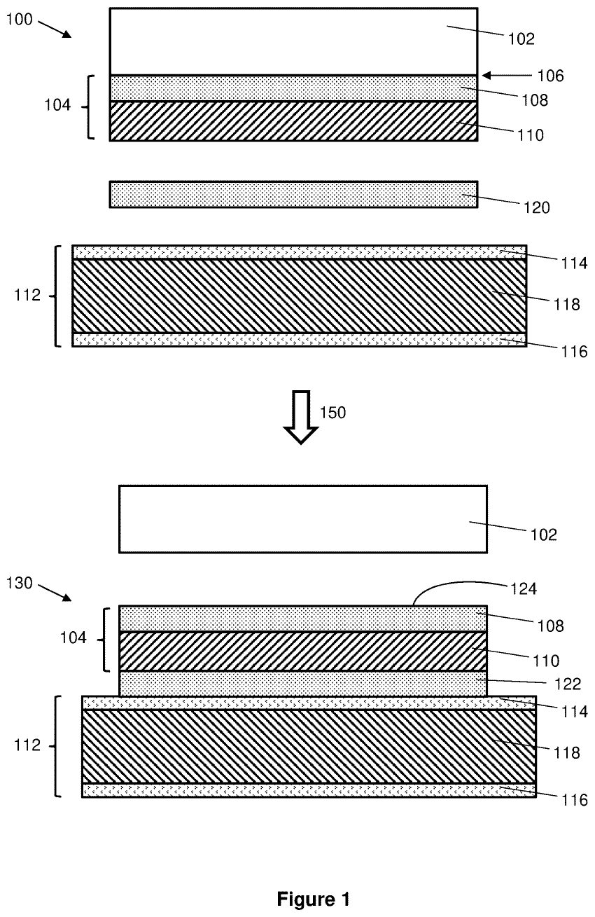

As seen in FIG. 1, transferrable photovoltaic device arrangement 100 includes flexible release substrate 102, which may comprise a flexible polymeric film. Thin-film photovoltaic device 104 is located on flexible release substrate 102, with interface 106 between the flexible release substrate and the photovoltaic device. As will be explained in greater detail hereafter, interface 106 is engineered to release thin-film photovoltaic device 104 once photovoltaic device 104 is adhered to a bottom photovoltaic sub-cell. Thin-film photovoltaic device 104 includes at least a solution-processed transparent conductive layer 108 located over the flexible release substrate and a photoactive layer 110 located over layer 108. Transparent conductive layer 108 will ultimately form a top electrical contact surface of the tandem photovoltaic solar cell, while photoactive layer 110 is a light-absorbing semiconductor layer with a bandgap suitable for the top sub-cell photoactive layer of a tandem photovoltaic solar cell, for example a perovskite photoactive layer. Thin-film photovoltaic device 104 may optionally include other layers (not shown) such as charge transport layers (i.e. electron-selective and/or hole-selective layers) interposed between transparent conductive layer 108 and photoactive layer 110 and/or located over photoactive layer 110.

Transferrable photovoltaic device arrangement 100 is configured to transfer thin-film photovoltaic device 104 to bottom photovoltaic sub-cell 112 to produce a tandem photovoltaic cell 130, as also shown in FIG. 1.

The present invention thus further relates to a method of producing a tandem photovoltaic cell. The method comprises providing a transferrable photovoltaic device arrangement as disclosed herein, and adhering the thin-film photovoltaic device of the transferrable photovoltaic device arrangement to a bottom photovoltaic sub-cell with a transparent conductive adhesive. The thin-film photovoltaic device is thereby functionally coupled to the bottom photovoltaic sub-cell via a second transparent conductive layer. The flexible release substrate of the transferrable photovoltaic device arrangement is then separated from the thin-film photovoltaic device. The resultant tandem photovoltaic cell has the first transparent conductive layer of the thin-film photovoltaic device at an outer conductive surface, and the second transparent conductive layer as a recombination layer or tunnel junction between the top and bottom sub-cells.

With ongoing reference to FIG. 1, transferrable photovoltaic device arrangement 100 is used in such a transfer method (represented by arrow 150) to transfer thin-film photovoltaic device 104 to bottom photovoltaic sub-cell 112. Bottom photovoltaic sub-cell 112 includes at least top conductive layer 114, bottom electrical contact 116 and photoactive semiconductor layer 118, and in some embodiments is a conventional silicon photovoltaic solar cell. Thin-film photovoltaic device 104 is thus adhered to top conductive layer 114 of the bottom sub-cell with a transparent conductive adhesive 120, so that thin-film photovoltaic device 104 and bottom photovoltaic sub-cell 112 are functionally coupled via transparent conductive layer 122. Transparent conductive layer 122, formed from transparent conductive adhesive 120, thus forms a recombination layer or tunnel junction between the top and bottom sub-cells in tandem photovoltaic cell 130.

In some embodiments, transparent conductive layer 122 is present initially as a pre-formed outer layer of thin-film photovoltaic device 104, located over photoactive layer 110. In other embodiments, transparent conductive layer 122 is present initially as a pre-formed outer layer of bottom photovoltaic sub-cell 112, either located over top conductive layer 114 or as top conductive layer 114. In yet further embodiments, transparent conductive adhesive 120 may be applied as a coating to the surface of either thin-film photovoltaic device 104 or bottom photovoltaic sub-cell 112 as part of the transfer method.

The transfer method also includes a step of separating flexible release substrate 102 from thin-film photovoltaic device 104. The separation step, which typically occurs by peeling off the flexible substrate to progressively break interface 106, may occur near-simultaneously with the adhesion of thin-film photovoltaic device 104 to bottom photovoltaic sub-cell 112 or as a separate operation at a later time. In either case, the separation of the flexible substrate relies on the adhesion or cohesion at interface 106 being weaker, at least at the time of separation, than: (i) the adhesion of thin-film photovoltaic device 104 to bottom photovoltaic sub-cell 112 via transparent conductive layer 122, and (b) the adhesion and cohesion between and within other functional layers in the tandem photovoltaic cell 130. Following the separation step, tandem photovoltaic cell 130 has transparent conductive layer 108 at an outer conductive surface 124, through which current can be drawn when the tandem cell is in operation.

### Definitions

Where the terms “comprise”, “comprises” and “comprising” are used in the specification (including the claims) they are to be interpreted as specifying the stated features, integers, steps or components, but not precluding the presence of one or more other features, integers, steps or components, or group thereof.

As used herein, the terms “first”, “second”, “third” etc in relation to various features of the disclosed arrangements, devices and methods are arbitrarily assigned labels and are merely intended to differentiate between two or more such features that may be incorporated in various embodiments. The terms do not of themselves indicate any particular orientation or sequence. Moreover, it is to be understood that the presence of a “first” feature does not imply that a “second” feature is present, the presence of a “second” feature does not imply that a “first” feature is present, etc.

As used herein, the terms “top” and “bottom” are referenced relative to the top light-receiving surface in the tandem photovoltaic cell, which is the first transparent conductive layer.

As used herein, the term “over”, especially in relation to functional layers of the transferrable photovoltaic device arrangement, indicates a relative position in a multilayered device structure which includes both “directly in contact with” and “separated by one or more interposed functional layers”. Thus, if layer B is over layer A, and layer C is over layer B, then the multilayered device structure can include the following layer sequences: A-B-C, A-X-B-C, A-B-X-C and A-X-B-X-C, where X is one or more interposed functional layers.

As used herein, the term “conductive layer” means a thin film with sufficient electrical conductivity to transport photo-generated charges through the layer. A conductive layer may be an electrical conductor or a semiconductor. A “conductive layer” can have multiple functions including charge selectivity.

As used herein, an “activatable” layer, adhesive or adhesive polymer is adapted to be functionally activated, for adhesion or debonding as required, by an external stimulus such as heat, radiation (e.g. actinic light) or chemical treatment.

### Transferrable Photovoltaic Device Arrangement

### Flexible Release Substrate

The transferrable photovoltaic device arrangement includes a flexible release substrate. The flexible release substrate is typically a flexible film, which can thus be separated from the thin-film photovoltaic device by peeling it away. In some embodiments, the flexible substrate is the form of a roll of film or tape to facilitate (i) fabrication of the thin-film photovoltaic device thereon in a roll-to roll manufacturing process and/or (ii) transfer of the thin-film photovoltaic device to a bottom photovoltaic sub-cell in a roll lamination process. Alternatively, the release substrate may be formed as flat sheets of flexible film. The flexible release substrate may comprise a flexible polymeric film, for example a polyester such as polyethylene terephthalate (PET) or polyethylene naphthalate (PEN), a polyolefin such as polypropylene or a fluorinated polymer such as ethylene tetrafluoroethylene (ETFE), as is typical for substrates in roll manufacturing processes. However, it is not excluded that the flexible release substrate can be made of other materials, such as metallic foils or paper.

In some embodiments, the release substrate comprises a non-stick surface, so that the flexible release substrate is readily separable from the thin-film photovoltaic device by delaminating the adjacent transparent conductive layer from the non-stick surface. As will be appreciated by the skilled person, a non-stick surface is inherently weakly susceptible to adhesion due to a low surface energy composition at its surface, and therefore does not require heat-activation to acquire non-stick properties. Suitable non-stick surfaces may have a surface energy of less than 36 Dyne/cm, preferably less than 30 Dyne/cm, for example as measured according to ASTM D7490-13. Non-stick surfaces may be provided by a low surface energy polymer, for example polymers selected from the group consisting of a fluorinated polymer, such as polytetrafluoroethylene (PTFE), and a silicone polymer, such as polydimethylsiloxane (PDMS). The non-stick surface may be a surface of a non-stick coating on the flexible release substrate. Suitable non-stick coatings are generally coatings of low surface energy polymers as described above. Alternatively, the flexible release substrate may comprise a self-supporting film of a suitable low surface energy polymer, and the non-stick surface is the surface of that film.

### Low Cohesion Sacrificial Layer

In some embodiments, the transferrable photovoltaic device arrangement includes a low-cohesion sacrificial layer interposed between the flexible release substrate and the first transparent conductive layer of the thin-film photovoltaic device. As used herein, the low-cohesion sacrificial layer is a layer having cohesive forces within the layer which are intentionally weaker than the adhesive forces between other layers, and the cohesive forces within other layers, in the multi-layered structure obtained when the thin-film photovoltaic device is adhered to the bottom sub-cell via a layer of transparent conductive adhesive. The low-cohesion sacrificial layer is either an intrinsically low-cohesion layer, i.e. at room temperature, or has suitably low cohesion when activated. In either case, the flexible release substrate is separable from the thin-film photovoltaic device by preferentially breaking the low-cohesion sacrificial layer. It will be appreciated, however, that the low-cohesion sacrificial layer nevertheless requires sufficient cohesive integrity and adhesive character so that the flexible release substrate can adhere to and support the thin-film photovoltaic device during fabrication and while transferring the thin-film photovoltaic device to a bottom sub-cell.

The low-cohesion sacrificial layer transparent is preferably a very thin layer, for example having a thickness of less than 100 nm, or less than 50 nm, or less than 20 nm. In some embodiments, the low-cohesion sacrificial layer is conductive due to the incorporation of a conductive component such as a metal, a metal oxide, and a conductive polymer or polymer composite (such as poly(3,4-ethylenedioxythiophene) polystyrene sulfonate, i.e. PEDOT:PSS). The inclusion of a conductive component may advantageously mitigate any loss of electrical conductivity through the surface of the first transparent conductive layer if residues of the low-cohesion sacrificial layer remain on that layer following the separation and removal of the flexible release substrate.

In some embodiments, the low-cohesion sacrificial layer comprises a low-cohesion organic non-polymeric solid, such as a wax. In some embodiments, the low-cohesion sacrificial layer comprises an activatable adhesive. The activatable adhesive may be activated, to sufficiently reduce the cohesion of the sacrificial layer, by any suitable external stimulus applied on command, such as heat or radiation. The flexible release substrate can therefore be separated from the thin-film photovoltaic device by activating the activatable adhesive by heat or radiation and breaking the low-cohesion sacrificial layer.

In some embodiments, the activatable adhesive in the sacrificial layer is a heat-activatable adhesive, such as a thermoplastic polymer selected from the group consisting of an ethylene-vinyl acetate (EVA) copolymer, a polyethylene, a polyethyleneoxide (PEO) and a polystyrene (PS). The thermoplastic polymer responds to the application of heat by melting or softening, thus lowering the cohesion of the sacrificial layer as required. Preferably, the activation occurs at temperatures which can be achieved when pressing the transferrable photovoltaic device arrangement onto the bottom sub-cell, and without damaging other layers in the device. In some embodiments, the sacrificial layer is heat-activatable, to sufficiently lower the cohesion thereof, at a temperature in the range of 50° C. to 170° C., such as in the range of 90° C. to 140° C.

In other embodiments, the activatable adhesive in the sacrificial layer is a light-depolymerizable polymeric composition, optionally including a suitable photoinitiator or photocatalyst. Examples include a polymeric composition selected from the group consisting of poly(phthalaldehyde) (PPHA) combined with photo acid generator (PAG), poly(acetal)s combined with PAG and polylactide (PLA) combined with TiO₂. The light-depolymerizable polymeric composition responds to irradiation with a suitable wavelength light by depolymerising or decrosslinking, thus lowering the cohesion of the sacrificial layer as required.

### Thin-Film Photovoltaic Device

The transferrable photovoltaic device arrangement comprises a thin-film photovoltaic device located over the flexible release substrate, with the interface configured to allow separation of the flexible substrate. A thin-film photovoltaic device generally has a multilayer architecture formed by a sequence of thin-film functional layers. In some embodiments, each functional layer has a dry layer thickness of less than 50 μm. In embodiments, each functional layer has a dry layer thickness of less than from 10 μm, or less than 5 μm or less than 2 μm.

Due to this architecture, thin-film photovoltaic devices are generally not self-supporting (i.e. they are physically unstable) and must therefore be fabricated and manipulated on a supportive substrate, here the flexible release substrate itself, by methods to be described hereafter. Once transferred to a bottom sub-cell, as disclosed herein, the thin-film photovoltaic device will become the top sub-cell in the resultant tandem photovoltaic cell.

### First Transparent Conductive Layer

The thin-film photovoltaic device includes a first transparent conductive layer, which is a solution-processed layer and comprises at least one organic, and typically polymeric, conductive and/or binder component selected from a conductive polymer or polymer composite, an activatable adhesive, and an organic binder. Advantageously, the organic or polymeric components may also improve the flexibility and resilience of the first transparent conductive layer, ensuring that its physical integrity and conductivity persists despite flexing and compression applied to the layer during transfer of the thin-film photovoltaic device to a bottom photovoltaic sub-cell.

The first transparent conductive layer is destined to become an outer conductive layer of the top sub-cell in a tandem photovoltaic cell. In the transferrable photovoltaic device arrangement, however, the first transparent conductive layer is located over the flexible release substrate, and may be directly in contact with that substrate or separated therefrom by an interposed sacrificial layer. The interface between the flexible release substrate and the solution-processed first transparent conductive layer is engineered to facilitate release and separation of the flexible release layer once the thin-film photovoltaic device is adhered to the bottom sub-cell. Consistent with the preferred methods of production to be disclosed hereafter, the first transparent conductive layer may be produced on the release substrate by solution-processing techniques such as coating or printing.

To provide the requisite conductivity, the first transparent conductive layer comprises at least one conductive component, optionally held together by a binder (for example if the conductive component is a particular non-polymeric material which requires consolidation). In some embodiments, the first transparent conductive layer comprises a conductive component selected from the group consisting of a metal, a metal oxide, a conductive polymer or polymer composite, a fullerene or functionalised derivative thereof, a carbon nanomaterial (such as graphene), a non-polymeric organic semiconductor, an organic aromatic compound and a non-polymeric conjugated organic compound. In some embodiments, the first transparent conductive layer comprises a conductive component selected from the group consisting of a metal, a metal oxide, and a conductive polymer or polymer composite. Suitable metal and metal oxides may include particulate nanomaterials including metallic (such as silver) nanowires, other metallic nanoparticles and nanoparticulate transparent conducting oxides such as indium tin oxide, zinc oxide, tin oxide, and nickel oxide. In some embodiments, the first transparent conductive layer comprises, or consists of, a conductive polymer or polymer composite. A suitable conductive polymer composite is PEDOT:PSS.

In some embodiments, the first transparent conductive layer is an electrical conductor layer (i.e. with metal-like conduction properties). Suitable electrical conductor layers may include conductive metallic compositions such as Au, Ag, Al, Mg, Cu or suitable alloys thereof or the like. For example, such metallic compositions may be present as nanoparticles in a transparent conducting matrix (i.e. of conductive polymers) or may be consolidated by an organic binder.

In other embodiments the first transparent conductive layer is a semiconductive charge transport layer, such as an electron-selective transport layer or a hole-selective transport layer depending on the intended orientation of the top sub-cell. In use in the tandem photovoltaic cell, the first transparent conductive layer may thus cooperate with the top sub-cell's photoactive layer to selectively extract either the photovoltaically excited electrons, or the corresponding holes, to the outer conductive surface of the top sub-cell.

When the first transparent conductive layer is an electron-selective transport layer, it may include transparent conductive oxides such as at least one of tin oxide, nickel oxide, zinc oxide, titanium dioxide, tungsten trioxide or the like, fullerene derivatives such as [6,6]-phenyl-C61-butyric acid methyl ester (PC60BM) or [6,6]-phenyl-C70-butyric acid methyl ester (PC70BM), pristine fullerenes such as C60, C70 or the like, or functional polymers such as polyethyleneimine ethoxylated (PEIE), or the like.

When the first transparent conductive layer is a hole-selective transport layer, it may include a transparent conducting polymer such as at least one of 2,2′,7,7′-tetrakis-(N,N-di-4-methoxyphenylamino)-9,9′-spirobifluorene (spiro-OMeTAD), poly[(2,5-bis(2-hexyldecyloxy)phenylene)-alt-(5,6-difluoro-4,7-di(thiophen-2-yl)benzo[c][1,2,5]-thiadiazole)](PPDT2FBT), poly(3,4-ethylenedioxythiophene) (PEDOT), poly(3,4-ethylenedioxythiophene) and polystyrene sulfonate mixture (PEDOT:PSS), poly(4,4-dioctylcyclopentadithiophene); P3HT, doped P3HT (poly(3-hexylthiophene-2,5-diyl)), poly(triarylamine) (PTAA), poly[N-9″-heptadecanyl-2,7-carbazole-alt-5,5-(4′,7′-di-2-thienyl-2′,1′,3′-benzothiadiazole)](PCDTBT), poly[2,6-(4,4-bis-(2-ethylhexyl)-4H-cyclopenta[2,1-b;3,4-b′]dithiophene)-alt-4,7(2,1,3-benzothiadiazole)](PCPDTBT), poly(N-alkyldiketopyrrolopyrroledithienylthieno[3,2-b]thiophene) (DPP-DTT) or the like.

The first transparent conductive layer may include a transparent conductive adhesive containing an activatable adhesive component, as will be explained in greater detail hereafter. However, this is not essential since even non-activatable or non-tacky transparent conductive layers can be suitably laminated to a non-stick surface of the release substrate or to a low-cohesion sacrificial layer on the release substrate by solution-processing methods. The separation of the release substrate therefore need not rely on de-bonding triggered by activation of the first transparent conductive layer itself. For example, the inventors have found that a thin-film photovoltaic device comprising a PEDOT:PSS transparent conductive layer can be delaminated from either (i) a flexible release substrate with a non-stick silicone coating, or (ii) a flexible release substrate having a heat-activated low-cohesion sacrificial layer thereon, despite the absence of an activatable adhesive component in the transparent conductive layer.

In some embodiments, the first transparent conductive layer includes, or consists of, a transparent conductive adhesive. The first transparent conductive layer may thus comprise a first activatable adhesive, such that the flexible release substrate is separable from the thin-film photovoltaic device when the first activatable adhesive is activated. As used herein, an activatable adhesive is an adhesive composition, typically an adhesive polymeric composition, which is activatable to allow adhesive bonding and/or debonding by any applied stimulus, such as heat, radiation or chemical treatment. In principle, transparent conductive layers comprising an activatable adhesive may be formed on a wide range of flexible release substrates, since de-bonding of the interface is triggered by activation of the transparent conductive adhesive. The interface between the activated first transparent conductive layer and the flexible release substrate thus preferably becomes the weakest point in the structure following the activation, such that the activated transparent conductive layer separates intact. However, it is not excluded that some residue of the activated transparent conductive adhesive may remain on the flexible release substrate provided that a suitably continuous layer of transparent conductive adhesive remains present on the thin-film photovoltaic device following its transfer.

In some embodiments, the first transparent conductive layer comprises a heat-activatable adhesive, for example a heat-activatable adhesive polymer. The heat-activatable adhesive polymer may be a thermoplastic polymer selected from the group consisting of an ethylene-vinyl acetate (EVA) copolymer, a polyethylene, a polyethyleneoxide (PEO) and a polystyrene (PS). When such insulating polymers are present as the matrix of the first transparent conductive layer, it will be appreciated that a conductive component is also required to establish the necessary conductivity. Suitable conductive components include particulates comprising conductive metals or metal oxides, and conductive polymers such as PEDOT:PSS, polyaniline (PANI), poly acetylene, polypyrrole, polythienylene-vinylene, polythiophene, polyphenylene-vinylene, polyphenylene sulfide. In one such example, the first transparent conductive layer is composed of a thermoplastic EVA copolymer matrix with Ag-coated conductive microspheres as the conductive additive. In another approach, the first transparent conductive layer comprises a heat-activatable conductive polymer composition, for example PEDOT:PSS in combination with a polyhydric alcohol such as D-sorbitol (see e.g. J. Ouyang, Y. Yang, Adv. Mater. 2006, 18, 2141).

Suitable heat-activatable first transparent conductive layers are preferably adapted to activate at temperatures which can be provided when pressing the transferrable photovoltaic device arrangement onto the bottom sub-cell, without damaging other functional layers in the device. In some embodiments, the first transparent conductive layer is heat-activatable, to trigger de-bonding from the flexible release substrate, at a temperature in the range of 50° C. to 170° C., such as in the range of 90° C. to 140° C.

### Photoactive Layer

The thin-film photovoltaic device includes a photoactive layer which is destined to become the light-absorbing layer of the top sub-cell in a tandem photovoltaic cell. In the transferrable photovoltaic device arrangement, however, the photoactive layer is located over the first transparent conductive layer, either directly in contact with that layer or separated therefrom by one or more interposed layers, such as a charge transport layer. Consistent with the preferred methods of production to be disclosed hereafter, the photoactive layer may be a solution-processed layer and may be produced on the release substrate.

The photoactive layer includes a light-absorbing semiconductor with a bandgap which is higher than the bandgap of the bottom sub-cell to be used in the tandem photovoltaic cell. Silicon-based bottom sub-cells have a bandgap of about 1.1 eV. The highest power conversion efficiency of a tandem cell with a Si-PV sub-cell is expected when the bandgap of the top sub-cell photoactive layer is between 1.6 and 1.9 eV, although it will be appreciated that bandgaps higher and lower than this preferred range can also be accommodated. In some embodiments, therefore, the bandgap of the photoactive layer in the thin-film photovoltaic device is between 1.6 and 1.9 eV.

In some embodiments, the photoactive layer comprises a metal halide semiconductor. In some such embodiments, the metal halide semiconductor is a photoactive perovskite layer. Organic-inorganic hybrid perovskites are considered particularly suitable because the bandgap can be tuned to a desired target by adjusting the composition of the perovskite structure. Furthermore, perovskite layers can be fabricated in thin-film format by solution processing methods, including on flexible substrates in a roll-to-roll manufacturing process. Examples of such methods are disclosed in the international patent applications published as WO2016/115602 A1 and WO2020/073082 A1. The electrical properties of perovskites are highly tolerant of the defects which may result from solution processing methods. Perovskite photoactive layers typically have a dry layer thickness in the range of 0.5 to 1 μm.

Photoactive perovskite layers comprise a light-absorbing perovskite semiconductor that consists essentially of crystallites of the perovskite. A perovskite material can be represented by the formula AMX₃, where A is at least one cation, M is at least one cation and X is at least one anion. When the perovskite comprises more than one A cation, the different A cations may be distributed over the A sites in an ordered or disordered way. When the perovskite comprises more than one M cation, the different M cations may be distributed over the M sites in an ordered or disordered way. When the perovskite comprises more than one X anion, the different X anions may be distributed over the X sites in an ordered or disordered way. The symmetry of a perovskite comprising more than one A cation, more than one M cation or more than one X cation, will be lower than that of CaTiO₃. Perovskite is a crystalline compound. Thus, the layer of the perovskite semiconductor without open porosity typically consists essentially of crystallites of the perovskite. In a perovskite-type photoactive device, such as a photovoltaic cell, the photoactive layer can comprise an organic-inorganic perovskite-structured semiconductor. However, it should be appreciated that in some embodiments, the photoactive layer can be all inorganic, for example, CsPb(IₙX₁₋ₙ)₃ where X is a non-iodine halide.

The term “perovskite”, as used herein, refers to (a) a material with a three-dimensional crystal structure related to that of CaTiO₃ or (b) a material comprising a layer of material, wherein the layer has a structure related to that of CaTiO₃. Although both of these categories of perovskite may be used in the devices according to the invention, it is preferable in some circumstances to use a perovskite of the first category, (a), i.e. a perovskite having a three-dimensional (3D) crystal structure. Such perovskites typically comprise a 3D network of perovskite unit cells without any separation between layers. Perovskites of the second category, (b), on the other hand, include perovskites having a two-dimensional (2D) layered structure. Perovskites having a 2D layered structure may comprise layers of perovskite unit cells that are separated by (intercalated) molecules; an example of such a 2D layered perovskite is [2-(I-cyclohexenyl)ethylammonium]2PbBr₄. 2D layered perovskites tend to have high exciton binding energies, which favours the generation of bound electron-hole pairs (excitons), rather than free charge carriers, under photoexcitation. The bound electron-hole pairs may not be sufficiently mobile to reach the p-type or n-type contact where they can then transfer (ionise) and generate free charge. Consequently, in order to generate free charge, the exciton binding energy has to be overcome, which represents an energetic cost to the charge generation process and results in a lower voltage in a photovoltaic cell and a lower efficiency. In contrast, perovskites having a 3D crystal structure tend to have much lower exciton binding energies (on the order of thermal energy) and can therefore generate free carriers directly following photoexcitation. Accordingly, the perovskite semiconductor employed in the devices and processes of the present invention is preferably a perovskite of the first category, (a), i.e. a perovskite which has a three-dimensional crystal structure.

In some embodiments, the perovskite has the form AM(IₙX₁₋ₙ)₃, where: A is at least one cation, preferably selected from methylammonium ([CH₃NH₃]⁺) and formamidinium ([R₂N—CH═NR₂]⁺) and cesium, M is a metal, I is iodine, X is a noniodine halide, preferably selected from Br and Cl, and n is in the range of 0 to 1. M is preferably selected from Pb, Sn, Ge, Cs, Bi. Advantageously, the bandgap of such perovskite semiconductors can be continuously tuned within the range of 1.6 eV and 2.3 eV by substituting iodine with bromine, as disclosed in the international patent application published as WO2016/090179.

In some embodiments, the photoactive layer comprises an organic photovoltaic active layer, for example as used in polymer solar cells. Such photoactive layers generally comprise an organic polymer electron-donor material such as poly(3-hexylthiophene) (P3HT) or poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione))](PBDB-T) in combination with a fullerene-based electron-acceptor materials such as phenyl-C61-butyric acid methyl ester (PCBM) or a non-fullerene acceptor such as 3,9-bis(2-methylene-(3-(1,1-dicyanomethylene)-indanone))-5,5,11,11-tetrakis(4-hexylphenyl)-dithieno[2,3-d:2′,3′-d′]-s-indaceno[1,2-b:5,6-b′]dithiophene) (ITIC) or Y6. Organic photoactive layers are also advantageously amendable to fabrication in thin-film format by solution processing methods, including on flexible substrates in a roll-to-roll manufacturing process. An example of such methods is disclosed in Na et al, Advanced Functional Materials 2018, 6, 1805825.

### Charge Transport Layer(s)

The thin-film photovoltaic device may further comprise one or more transparent functional layers, in addition to the first transparent conductive layer and the photoactive layer. Consistent with the preferred methods of production to be disclosed hereafter, the transparent functional layers may be solution-processed layers and may be produced on the release substrate.

In some embodiments, the thin-film photovoltaic device further comprises a first charge transport layer interposed between the first transparent conductive layer and the photoactive layer, for example sandwiched between and in direct contact with these layers. In some embodiments, the thin-film photovoltaic device further comprises a second charge transport layer located over the photoactive layer, for example in direct contact with the photoactive layer. Such charge transport layers typically have a thickness of less than 0.2 μm, or less than 0.1 μm.

The first and second charge transport layers may be an electron-selective and a hole-selective transport layer, or vice versa, depending on the intended orientation of the top sub-cell. Such charge transport layers may assist to selectively extract the photovoltaically excited electrons and corresponding holes towards the outer conductive surface and the recombination layer/tunnel junction of the top sub-cell, respectively, thus providing an improved photovoltaic performance. However, as the skilled person will appreciate, charge transport layers are not essential to in solar cell architectures and either or both of the first and second charge transport layers may therefore be absent.

Suitable electron-selective transport layers may include transparent conductive oxides such as at least one of tin oxide, zinc oxide, titanium dioxide or the like, fullerene derivatives such as [6,6]-Phenyl-C61-butyric acid methyl ester (PC60BM) or [6,6]-Phenyl-C70-butyric acid methyl ester (PC70BM), pristine fullerene mixtures such as C₆₀, C₇₀ or the like, or transparent conductive polymers such as polyethylenimine ethoxylated (PEIE), or the like.

Suitable hole-selective transport layers may include a transparent conducting polymer such as at least one of 2,2′,7,7′-tetrakis-(N,N-di-4-methoxyphenylamino)-9,9′-spirobifluorene (spiro-OMeTAD), poly[(2,5-bis(2-hexyldecyloxy)phenylene)-alt-(5,6-difluoro-4,7-di(thiophen-2-yl)benzo[c][1,2,5]-thiadiazole)](PPDT2FBT), poly(3,4-ethylenedioxythiophene) (PEDOT), poly(3,4-ethylenedioxythiophene and polystyrene sulfonate mixture (PEDOT:PSS), poly(4,4-dioctylcyclopentadithiophene); P3HT, doped P3HT (poly(3-hexylthiophene-2,5-diyl)), poly(triarylamine) (PTAA), poly[N-9″-heptadecanyl-2,7-carbazole-alt-5,5-(4′,7′-di-2-thienyl-2′,1′,3′-benzothiadiazole)](PCDTBT), poly[2,6-(4,4-bis-(2-ethylhexyl)-4H-cyclopenta[2,1-b;3,4-b′]dithiophene)-alt-4,7(2,1,3-benzothiadiazole)](PCPDTBT), poly(N-alkyldiketopyrrolopyrroledithienylthieno[3,2-b]thiophene) (DPP-DTT), MoO₃ or the like.

### Second Transparent Conductive Layer

In some embodiments, the thin-film photovoltaic device of the transferrable photovoltaic device arrangement includes a second transparent conductive layer. The second transparent conductive layer is located over the photoactive layer, either directly in contact with the photoactive layer or separated therefrom by one or more interposed layers, such as a charge transport layer. The second transparent conductive layer, which is present as the outer layer of the thin-film photovoltaic device, comprises a transparent conductive adhesive for adhering the thin-film photovoltaic device to a bottom photovoltaic sub-cell. Advantageously, the thin-film photovoltaic device can thus be adhered to a bottom sub-cell, such as a silicon-based cell, by simply bringing the two layers into contact under conditions where the transparent conductive adhesive bonds to the bottom sub-cell.

Consistent with the preferred method of production to be disclosed hereafter, the second transparent conductive layer may be a solution-processed layer and may be produced on the release substrate.

Preferred transparent conductive adhesives for the second transparent conductive layer have the following characteristics: (i) able to adhesively bond to a bottom sub-cell, optionally after first being activated by an external stimulus, with sufficient adhesive strength that the flexible release substrate can be peeled off the thin-film photovoltaic device; (ii) able to form a durable adhesive interlayer between the top and bottom sub-cells, thus forming a monolithic tandem photovoltaic device; (iii) high optical transparency to the photons which transmit through the top sub-cell for absorption in the photoactive layer of the bottom sub-cell; and (iv) electronic properties suitable to allow the hole current from one sub-cell to recombine with the electron current from the other sub-cell with low voltage loss.

The transparent conductive adhesive includes a second conductive component, which may comprise at least one selected from the group consisting of a metal, a metal oxide, a conductive polymer or polymer composite, a fullerene or functionalised derivative thereof, a carbon nanomaterial (such as graphene), a non-polymeric organic semiconductor, an organic aromatic compound and a non-polymeric conjugated organic compound. In some embodiments, the second conductive component comprises at least one selected from the group consisting of a metal, a metal oxide, and a conductive polymer or polymer composite.

In some embodiments, the transparent conductive adhesive comprises an activatable adhesive, such that the second transparent conductive layer is adherent to the bottom photovoltaic sub-cell when the activatable adhesive is activated. The activatable adhesive may be activatable by any applied stimulus, such as heat, radiation or chemical treatment.

If heat-activatable, the second transparent conductive layer is preferably adapted to activate at temperatures which can be provided when pressing the transferrable photovoltaic device arrangement onto the bottom sub-cell, without damaging other functional layers in the device. In some embodiments, the second transparent conductive layer is heat-activatable, to facilitate adhesion to the bottom sub-cell, at a temperature in the range of 50° C. to 170° C., such as in the range of 90° C. to 140° C.

In some embodiments, the transparent conductive layer is heat-activatable at a temperature sufficiently high to also release the flexible release substrate from the thin-film photovoltaic device. For example, either the first transparent conductive layer or a low-cohesion sacrificial layer, as described herein, may comprise a first heat-activatable adhesive polymer and the second transparent conductive layer comprises a second heat-activatable adhesive polymer. The two heat-activatable adhesive polymers are selected such that a single heat-treatment step causes (i) de-bonding at the interface between the flexible release film and the thin-film photovoltaic device, and (ii) activation and adhesion of the second transparent conductive layer to the bottom photovoltaic sub-cell. For example, the second heat-activatable adhesive polymer may have a higher melting point than the first heat-activatable adhesive polymer. Thus, if the transferrable photovoltaic device arrangement is hot-pressed onto a bottom photovoltaic sub-cell, for example in a roll lamination process, the separation of the flexible release substrate may be effected near-simultaneously with the adhesion of thin-film photovoltaic device to the bottom photovoltaic sub-cell.

In some embodiments, the activatable adhesive of the second transparent conductive layer is a thermoplastic polymer selected from the group consisting of an ethylene-vinyl acetate (EVA) copolymer, a polyethylene, a polyethyleneoxide (PEO) and a polystyrene (PS). When such insulating polymers are present as the matrix of the second transparent conductive layer, a conductive component is required to establish the necessary conductivity. The conductive component may comprise particulate conductive elements which establish a conductive pathway through the thickness of the second transparent conductive layer. In one such example, a transparent conductive adhesive suitable for a recombination layer is composed of a thermoplastic EVA copolymer matrix with Ag-coated conductive microspheres as the conductive additive (see T. R. Klein et al, J. Phys. D: Appl. Phys. 2021, 54, 184002).

The thermoplastic polymer may form a continuous matrix of the second transparent conductive layer or it may be present in non-continuous form. For example, the second transparent conductive layer may comprise a conductive polymer or composite such as PEDOT:PSS in combination with a particulate thermoplastic polymer. When heat-activated in use, the thermoplastic polymer flows and the layer becomes adherent to a bottom photovoltaic sub-cell.

In other embodiments, the second transparent conductive layer comprises a heat-activatable conductive polymer composition, for example PEDOT:PSS in combination with a polyhydric alcohol such as D-sorbitol (see e.g. J. Ouyang, Y. Yang, Adv. Mater. 2006, 18, 2141).

In some embodiments, the transparent conductive adhesive comprises a radiation-activatable adhesive, such that the second transparent conductive layer is adherent to the bottom photovoltaic sub-cell when the activatable adhesive is irradiated with suitable actinic light.

The second transparent conductive layer may be adapted to solidify or harden once it has been activated and adhered to the bottom sub-cell, thus forming a durable transparent conductive interlayer between the top and bottom sub-cells. This may simply involve cooling of a heat-activated adhesive to allow it to set again. In some embodiments, however, the second transparent conductive layer comprises an activatable adhesive which cures irreversibly by covalent bond forming reactions when activated, e.g. by heat or radiation. An example of such a conductive adhesive material is Panacol Elecolit 3065, available from Ulbricht.

In some embodiments, the transparent conductive adhesive comprises a pressure sensitive adhesive such that the second transparent conductive layer adheres to a bottom photovoltaic sub-cell when the thin-film photovoltaic device is pressed onto its top receipt surface. For example, the second transparent conductive layer may comprise PEDOT:PSS in combination with an acrylic microemulsion pressure sensitive adhesive (see e.g. D. Bryant et al, Adv. Mater. 2014, 26, 7499-7504)

### Configuration

The transferrable photovoltaic device arrangement may be configured as a roll, suitable for a roll lamination process in which the thin-film photovoltaic device is pressed onto the bottom photovoltaic sub-cell and the flexible release substrate is separated from the thin-film photovoltaic device. The flexible release substrate is thus configured, when unrolled, as an elongated film or tape. The thin-film photovoltaic device may be configured as a continuous or discontinuous strip extending along the elongated film, preferably with dimensions suitable to match a specific bottom photovoltaic sub-cell.

### Method of Producing a Transferrable Photovoltaic Device Arrangement

The invention also relates to a method of producing a transferrable photovoltaic device arrangement. The method comprises providing a flexible release substrate and producing a thin-film photovoltaic device on the flexible release substrate. This is done by successively forming a sequence of functional layers including at least a first transparent conductive layer over the flexible release substrate and a photoactive layer over the first transparent conductive layer. The first transparent conductive layer is formed by solution-processing and comprises at least one selected from a conductive polymer or polymer composite, an activatable adhesive, and an organic binder. The interface between the flexible release substrate and the first transparent conductive layer produced thereon is designed such that the flexible release substrate is separable from the thin-film photovoltaic device in use, thereby exposing the first transparent conductive layer at an outer conductive surface of the thin-film photovoltaic device.

A particular advantage of the methods disclosed herein is that low-cost and readily scalable solution processing techniques can be used to produce the functional layers. At least the first transparent conductive layer is formed by solution-processing, but in preferred embodiments at least one other, or at least two other, or all of the functional layers in the thin-film photovoltaic device are solution-processed functional layers.

Solution-processed functional layers are formed in a fabrication method in which the materials forming the layer are deposited while in solution (otherwise known as a “wet” processing method). This is in contrast to “dry” processing methods wherein such materials are deposited while in a gas or vapor phase. A solution-processed functional layer typically comprises the functional materials of the layer and optionally an organic binder. The wet solution used to form the solution-processed functional layer typically comprises the functional materials, or precursors thereof, and the optional binder mixed together within a solvent.

Organic binders are typically required when one or more functional materials of the solution-processed layer are particulate materials which require consolidation to form a suitably cohesive and adherent layer. Any suitable organic binder can be used. Examples of suitable organic binders include as one or more of ethyl cellulose, butyl cellulose, nitrocellulose, hydroxylcellulose, cellulose acetate butyrate, alkyd resins, epoxy resin, phenolic resins, acrylic resin, butyl carbitol, butadiene-styrene rubber, polyvinylpyrrolidone, polyacrylamide, and cellulose derivatives. Polymeric organic binders are particularly preferred.

Suitable solvents include, without limitation, dimethylformamide (DMF), dimethylsulfoxide (DMSO), acetonitrile, N-methyl-2-pyrrolidone (NMP), y-butyrolactone (GBL), terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, chloroform, diethylene glycol derivatives, toluene, xylene isopropanol, ethyl acetate, water, chlorobenzene, or a combination thereof.

The wet solution to produce each solution-processed functional layer can be applied as a wet film onto the immediately preceding layer using any suitable method, for example at least one of: casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, or dip coating. In exemplary embodiments, at least one, or at least two, or all of the functional layers are produced using at least one of blade coating, screen-printing, slot-die coating, gravure printing or reverse-gravure coating methods.

Once the wet film has been produced, the solvent is removed to produce the thin-film functional layer. A heat-treating step (also known as an annealing step) is typically used to remove solvent from the wet film, thus drying the functional layer. A heat-treating step is preferably conducted after each layer is applied. However, it should be appreciated that two or more layers could also be applied before the combined layers are heat treated. Various heat treatment regimens can be used, depending on the specific requirements of each functional layer. In some embodiments, heat treatment comprises heating the wet film to at least 80° C., preferably to at least 100° C. and more preferably to at least 120° C. In embodiments, the heat treatment regime is conducted for 0 to 10 minutes.

Solution-processed functional layers can advantageously be produced on flexible substrates by roll-to-roll manufacturing techniques, which are amenable to low cost and high throughput production at scale. In some embodiments, therefore, the first transparent conductive layer is produced by roll-to-roll processing. In some embodiments, at least one, or at least two, or all of the functional layers are produced by roll-to-roll processing.

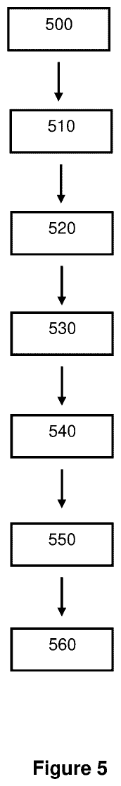

The method of producing a transferrable photovoltaic device arrangement will now be described with reference to FIG. 5. The method includes step 500 of providing a flexible release substrate, which is generally as described herein in relation to the transferrable photovoltaic device arrangement. Suitable flexible release substrates may be available from commercial sources. In some embodiments, the flexible release substrate is configured as a roll, so that the thin-film photovoltaic device may then be produced on the flexible release substrate by a sequence of coating and/or printing steps in a roll-to-roll manufacturing process.

In some embodiments, the flexible release substrate comprises a non-stick surface, as previously described. The first transparent conductive layer will then be formed directly on the non-stick surface. In some embodiments, the flexible release substrate comprises a low-cohesion sacrificial layer, as previously described herein, on its surface.

The method may thus include an optional step 510 of forming a low-cohesion sacrificial layer on the flexible release substrate. This may be done by applying a fluid composition, comprising the components of the sacrificial layer, to form a wet film over the flexible release substrate and solidifying the wet film to form the low-cohesion sacrificial layer. The fluid composition may include a solvent which is removed from the wet film, typically by heating, to form the low-cohesion sacrificial layer. Despite its intrinsic or activatable low-cohesion character, the sacrificial layer as produced nevertheless has sufficient cohesive integrity and adhesive character that the subsequent layers can be fabricated and supported thereon.

The method includes a step 520 of forming a first transparent conductive layer, as previously described herein, over the flexible release substrate by solution processing. The first transparent conductive layer may be formed directly on the flexible release substrate or on an interposed low-cohesion sacrificial layer (e.g. as formed in optional step 510). The first transparent conductive layer may be formed by applying a fluid composition to form a wet film over the flexible release substrate and solidifying the wet film to form the first transparent conductive layer over the flexible release substrate. The fluid composition may include a solvent which is removed from the wet film, typically by heating, to form the first transparent conductive layer.

The fluid composition includes the required conductive component(s), as previously described herein, or reactive precursor(s) thereof. Reactive precursors may include reactive metal compounds, such as metal halides or metal alkoxides, which form transparent conductive metal oxides in situ by reacting with moisture. Examples of such compositions include titanium chloride, titanium 2-propoxide and zinc acetate solutions, with and without dopants. The fluid composition may include an organic binder and/or an activatable adhesive, and will contain at least one such component if the conductive component is not itself polymeric. Suitable activatable adhesives, for example a heat-activatable adhesive polymer, will adhere the first transparent conductive layer to the underlaying layer but can subsequently be activated to release the flexible release substrate from the thin-film photovoltaic device.

The method may include optional step 530 of forming one or more transparent functional layers, such as a charge transport layer as previously described herein, on the first transparent conductive layer. An electron-selective transport layer or a hole-selective transport layer may be produced by applying a fluid composition, comprising the charge transport component(s) or reactive precursor(s) thereof, to form a wet film on the first transparent conductive layer and solidifying the wet film to form the charge transport layer. The fluid composition may include a solvent which is removed from the wet film, typically by heating, to form the charge transport layer.

The method includes a step 540 of forming a photoactive layer, as previously described herein, over the first transparent conductive layer. The photoactive layer may be formed directly on the first transparent conductive layer or on an interposed transparent functional layer such as a charge transport layer formed in optional step 530. The photoactive layer may be produced by applying a flowable composition, comprising one or more photoactive layer components or precursors thereof dispersed in a solvent, to form a wet film over the first transparent conductive layer; and forming the photoactive layer by removing the solvent from the wet film.

The flowable composition may be a perovskite precursor solution, which contains dissolved ionic components which crystallise into a photoactive perovskite structure when a wet film of the perovskite precursor solution is concentrated by drying. One way to prepare suitable perovskite precursor solutions is simply to dissolve the required perovskite composition in a sufficiently volatile polar solvent, such as dimethylformamide. Optionally, the perovskite precursor solution is applied to only a part of the underlying layer (e.g. a charge transport layer) and allowed to spread across the intended footprint in response to adhesive forces between the polar perovskite precursor solution and the hydrophilic underlying layer, as disclosed in the international patent application published as WO2020/073082.

The photoactive layer may also be formed by successively applying two or more flowable compositions which together form the photoactive layer. Examples of this approach, in which two perovskite precursor solutions are successively applied to form a perovskite photoactive layer, are disclosed in the international patent application published as WO2016/115602.

The flowable composition may be for producing an organic photovoltaic active layer, and may thus contain photoactive layer components including an organic polymer electron-donor material and a fullerene or non-fullerene acceptor.

The method may include optional step 550 of forming one or more transparent functional layers, such as a charge transport layer as previously described herein, on the photoactive layer. An electron-selective transport layer or a hole-selective transport layer may be produced by applying a fluid composition, comprising the charge transport component(s) or reactive precursor(s) thereof, to form a wet film on the photoactive layer and solidifying the wet film to form the charge transport layer. The fluid composition may include a solvent which is removed from the wet film, typically by heating, to form the charge transport layer.

The method may include optional step 560 of forming a second transparent conductive layer, as previously described herein, over the photoactive layer. The second transparent conductive layer includes a transparent conductive adhesive for adhering the thin-film photovoltaic device to a bottom photovoltaic sub-cell. The second transparent conductive layer, as previously described herein, may be formed directly on the photoactive layer or on an interposed transparent functional layer, such as a charge transport layer formed in optional step 550. The second transparent conductive layer may be formed by applying a fluid composition to form a wet film over the photoactive layer and solidifying the wet film to form the second transparent conductive layer. The fluid composition may include a solvent which is removed from the wet film, typically by heating, to form the second transparent conductive layer. The fluid composition will also comprise the components of the transparent conductive adhesive, such as an activatable adhesive and a conductive component or reactive precursor thereof.

### Method of Producing a Tandem Photovoltaic Cell

The invention also relates to a method of producing a tandem photovoltaic cell. The method comprises providing a transferrable photovoltaic device arrangement as disclosed herein, or as produced by a method as disclosed herein. The thin-film photovoltaic device of the transferrable photovoltaic device arrangement is adhered to a bottom photovoltaic sub-cell with a transparent conductive adhesive. The thin-film photovoltaic device and the bottom photovoltaic sub-cell are thereby functionally coupled via a second transparent conductive layer, which forms the recombination layer or tunnel junction in the tandem photovoltaic cell. The flexible release substrate of the transferrable photovoltaic device arrangement is separated from the thin-film photovoltaic device, thus exposing the first transparent conductive layer. The resultant tandem photovoltaic cell therefore has the first transparent conductive layer of the thin-film photovoltaic device at an outer conductive surface.

The bottom photovoltaic sub-cell may in principle be any type of photovoltaic cell with a suitable bandgap for the bottom sub-cell of a tandem photovoltaic cell, including a silicon photovoltaic cell, a copper indium gallium (di)selenide (CIGS) photovoltaic cell, a cadmium telluride (CdTe) photovoltaic cell, or a perovskite photovoltaic cell. The bottom photovoltaic sub-cell generally has a conventional architecture, including a photoactive (light-absorbing) layer, and a bottom electrical contact (which may be opaque). The bottom photovoltaic sub-cell has a conductive outer layer with a receipt surface to which the thin-film photovoltaic device is adhered. The outer layer may be a highly doped Si layer (n-type or p-type) or a transparent conductive oxide layer.

In some embodiments, the bottom photovoltaic sub-cell is a silicon photovoltaic cell. The silicon photovoltaic cell may be a conventional p-n homojunction cell or a heterojunction silicon photovoltaic cell. In some embodiments, the bottom photovoltaic sub-cell has a rigid, planar structure. In some embodiments, the bottom photovoltaic sub-cell has a bendable, thin planar structure. In some embodiments, the bottom photovoltaic sub-cell is a textured crystalline silicon (c-Si) solar cell.

In some embodiments, the transparent conductive adhesive is present as a pre-formed outer layer of either the thin-film photovoltaic device or the bottom photovoltaic sub-cell. In such cases, the thin-film photovoltaic device and the bottom photovoltaic sub-cell are brought into contact to adhere them via the second transparent conductive layer. In other embodiments, the method may comprise an additional step of applying a coating of transparent conductive adhesive to the surface of either the thin-film photovoltaic device or the bottom photovoltaic sub-cell, before bringing them into contact.

In some embodiments, the transparent conductive adhesive is activated to facilitate the adhesion and/or curing of the second transparent conductive layer. The transparent conductive adhesive may be activated with heat, radiation or chemical treatment, either before or after bringing the thin-film photovoltaic device and the bottom photovoltaic sub-cell into contact.

In some embodiments, the transparent conductive adhesive is heat-activated, optionally at a temperature in the range of 50° C. to 170° C., such as in the range of 90° C. to 140° C. For example, the transferrable photovoltaic device arrangement may be hot-pressed onto the bottom photovoltaic sub-cell at a suitable temperature and dwell time to fluidise or soften the heat-activated adhesive polymers in the transparent conductive adhesive. The activated transparent conductive adhesive may thus become tacky and adherent to the receipt surface of the bottom photovoltaic sub-cell. Once the heated press is removed, the adhesive polymers cool and set, thus providing a permanent adhesive bond.

In some embodiments, the transparent conductive adhesive is radiation-activated. For example, the transferrable photovoltaic device arrangement is irradiated with actinic radiation, such as UV light, to facilitate initial adhesion to the bottom sub-cell and subsequent curing by covalent bond forming reactions to form a permanent adhesive bond.

The thin-film photovoltaic device may be pressed or compressed onto the bottom photovoltaic sub-cell to facilitate the adhesion. Any suitable compression/pressing process can be used. For example, the compression/pressing process can comprise roll pressing such as calender press/laminator, uniaxial pressing, or isostatic pressing. In embodiments, the thin-film photovoltaic device is applied to the bottom photovoltaic sub-cell by compression, preferably by a press arrangement, more preferably by a calender press.

In some embodiments, the thin-film photovoltaic device is progressively brought into contact with the bottom photovoltaic sub-cell. This may be done, for example, by calender-pressing the thin-film photovoltaic device arrangement onto the bottom photovoltaic sub-cell in a roll lamination process.

Sufficient adhesive bonding between the thin-film photovoltaic device and the bottom photovoltaic sub-cell is required to ensure that the flexible release substrate is selectively separated from the flexible release substrate when desired. It will be appreciated, however, that the thin-film photovoltaic device and bottom photovoltaic sub-cell need not be brought into contact across the entire intended interface before commencing the separation of the flexible release film. In a roll lamination process, for example, the thin-film photovoltaic device and bottom photovoltaic sub-cell need be in contact and adhered only beneath the separating interface between the flexible release substrate and the thin-film photovoltaic device. Furthermore, the ultimate adhesive bond strength of the interlayer between the thin-film photovoltaic device and the bottom photovoltaic sub-cell need not be fully developed by the time that the flexible release substrate is separated.

The flexible release substrate may be separated from the thin-film photovoltaic device at any time after the thin-film photovoltaic device is adhered to the bottom photovoltaic sub-cell beneath the separating interface. In some embodiments, the flexible release substrate is separated from the thin-film photovoltaic device in a subsequent process step, which may in principle be conducted at a different time and location. For example, the thin-film photovoltaic device arrangement may be adhered to the bottom photovoltaic sub-cell on one production line, and the flexible release substrate is separated and removed in a different production line or even during assembly of a solar cell module. In other embodiments, the thin-film photovoltaic device is adhered to the bottom photovoltaic sub-cell, and the flexible release substrate is separated from the thin-film photovoltaic device, in a single process, such that the two steps occur near-simultaneously (i.e. within a few minutes, preferably no more than a few seconds of each other).

As disclosed herein, the separation step comprises selectively breaking the interface between the flexible release substrate and the thin-film photovoltaic device. In some embodiments, for example when the flexible release substrate has a non-stick surface or an intrinsically low-cohesion sacrificial layer is interposed between the thin-film photovoltaic device and the flexible release substrate, the flexible release substrate can be separated and removed simply by progressively peeling away the release substrate once the thin-film photovoltaic device is adhered to the bottom photovoltaic sub-cell.

In other embodiments, for example when the first transparent conductive layer is activatable or an activatable low-cohesion sacrificial layer is interposed between the thin-film photovoltaic device and the flexible release substrate, separating the flexible release substrate from the thin-film photovoltaic device comprises an activation step. The activation step may comprise activating an activatable adhesive in either the first transparent conductive layer or the low-cohesion sacrificial layer, for example with heat or radiation.

In some embodiments, the activation step comprises heat-activating the first transparent conductive layer or the low-cohesion sacrificial layer at a temperature in the range of 50° C. to 170° C., such as in the range of 90° C. to 140° C. For example, the transferrable photovoltaic device arrangement may be hot-pressed onto the bottom photovoltaic sub-cell at a suitable temperature and dwell time to fluidise or soften the heat-activated adhesive polymers in the first transparent conductive layer or the low-cohesion sacrificial layer. This releases the adhesive bond between the flexible release substrate and the thin-film photovoltaic device, allowing the flexible release substrate to be peeled away. In other embodiments, the flexible release substrate is released by irradiating the first transparent conductive layer or the low-cohesion sacrificial layer with actinic light to activate an activatable adhesive, for example by a depolymerization mechanism.

In some embodiments, a single activation step is used to (i) release the flexible release layer from the thin-film photovoltaic device, thereby allowing its separation, and (ii) activate the transparent conductive adhesive, thereby adhering the thin-film photovoltaic device to the bottom photovoltaic sub-cell. In some embodiments, the thin-film photovoltaic device is adhered to the bottom photovoltaic sub-cell by activating the transparent conductive adhesive with heat at a temperature sufficient to release the flexible release substrate from the thin-film photovoltaic device. For example, the transferrable photovoltaic device arrangement may be hot-pressed onto the bottom photovoltaic sub-cell at a suitable temperature and dwell time to (i) heat-activate the transparent conductive adhesive to adhere the thin-film photovoltaic device to the bottom photovoltaic sub-cell, and (ii) heat-activate the first transparent conductive layer or the low-cohesion sacrificial layer to release the adhesive bond between the flexible release substrate and the thin-film photovoltaic device.

In some embodiments, the transferrable photovoltaic device arrangement is configured as a roll, and the thin-film photovoltaic device is transferred to a bottom photovoltaic sub-cell in a roll lamination process.

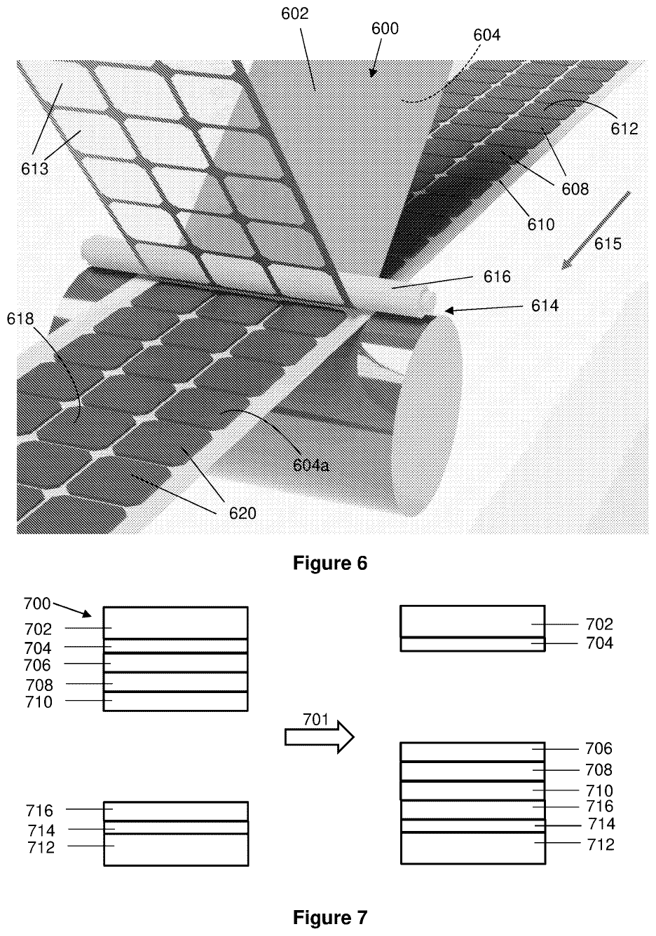

A method of producing a tandem photovoltaic cell in a roll lamination process will be described with reference to FIG. 6. Transferrable photovoltaic device arrangement 600 includes flexible release substrate 602 and thin-film photovoltaic device 604 disposed as a continuous strip thereon (covering the entire unseen underside of flexible release substrate 602 in FIG. 6). The interface between flexible release substrate 602 and a transparent conductive inner layer of thin-film photovoltaic device 604 is designed to allow separation, as disclosed herein. Thin-film photovoltaic device 604 includes a layer of transparent conductive adhesive on its outer surface.

A plurality of bottom Si-PV sub-cells 608 are held on a rigid moving stage 610, each Si-PV sub-cell including a conductive outer layer with a receipt surface 612 for receiving a thin-film photovoltaic device 604. Moving stage 610 and transferrable photovoltaic device arrangement 600 are both passed through calender press 614 in the direction indicated by arrow 615. Arrangement 600, initially configured as a roll (not shown) is thus unwound and brought into contact with bottom Si-PV sub-cells 608. Calender roll 616 presses thin-film photovoltaic device 604 onto receipt surfaces 612 for a sufficient dwell time to adhere the layer of transparent conductive adhesive thereto. Optionally, calender roll 616 is heated and applies a temperature sufficient to heat-activate the transparent conductive adhesive, thus facilitating the adhesion.

After the laminated structure emerges from the opposite side of calender press 614, flexible release substrate 602 is pulled away from moving stage 610 and optionally rewound onto another roll. Because the interface between the flexible release substrate 602 and thin-film photovoltaic device 604 is the weakest interface following roll lamination, flexible release substrate 602 is selectively peeled away wherever thin-film photovoltaic devices 604 is adhered to a bottom Si-PV sub-cell 608, i.e. from cut-out regions 613 of flexible release substrate 602. Tandem photovoltaic cells 620 are thus formed with (i) a transparent conductive layer (i.e. the transparent conductive adhesive) forming the recombination layer or tunnel junction between the bottom Si-PV sub-cell and the transferred thin-film photovoltaic device 604a (the top sub-cell), and (ii) transparent conductive layer 618 of thin-film photovoltaic device 604a exposed at the outer surface. The release of flexible release substrate 602 from transparent conductive layer 618 may be facilitated by the heating optionally applied by calender roll 616, which heat-activates the transparent conductive layer 618 itself or an interposed low cohesion sacrificial layer. Alternatively, flexible release substrate 602 may have a non-stick surface such that the interface between flexible release substrate 602 and transparent conductive layer 618 is inherently detachable (i.e. without activation).

The separation of the flexible release substrate from the thin-film photovoltaic device exposes the first transparent conductive layer at an outer conductive surface of the tandem photovoltaic cell. The removal of the insulating release substrate advantageously allows current to flow through the outer surface of the tandem cell when in operation. On large surface area tandem photovoltaic cells, however, it is still necessary to collect the current via a metallic current collector network on the outer sun-receiving surface. In some embodiments, therefore, the method further comprises producing a metallic current collector network on the outer conductive surface of the tandem photovoltaic cell, for example a silver metal grid as typically applied to the outer surface of commercially-sized silicon photovoltaic cells. Optionally, one or more additional transparent conducting layers (e.g. vacuum-processed transparent conductive oxides) may also be produced on the first transparent conductive layer of the tandem photovoltaic cell. The metallic current collector network may then be produced on the new conductive surface provided thereby.

### Tandem Photovoltaic Cells

The invention also relates to a tandem photovoltaic cell arrangement comprising a bottom photovoltaic sub-cell and a transferrable photovoltaic device arrangement as disclosed herein, wherein the thin-film photovoltaic device is adhered to the bottom photovoltaic sub-cell via a second transparent conductive layer comprising a transparent conductive adhesive. The bottom photovoltaic sub-cell may be as previously disclosed herein, and in some exemplary embodiments is a silicon photovoltaic cell.

In some embodiments, the flexible release substrate remains unseparated from the thin-film photovoltaic device. However, the interface between the flexible release substrate and the thin-film photovoltaic device is engineered to allow its removal when desired by peeling it away, optionally after first releasing the interface by applying a suitable external stimulus such as heat or radiation.

In other embodiments, the flexible release substrate is partially separated from the thin-film photovoltaic device, thereby exposing the first transparent conductive layer at an outer conductive surface. Such arrangements may be intermediate structures obtained when manufacturing tandem photovoltaic cells according to the methods disclosed herein.

Once the flexible release substrate is fully separated, the tandem photovoltaic cell is produced. The invention thus also relates to a tandem photovoltaic cell, produced by the methods disclosed herein.

### EMBODIMENTS

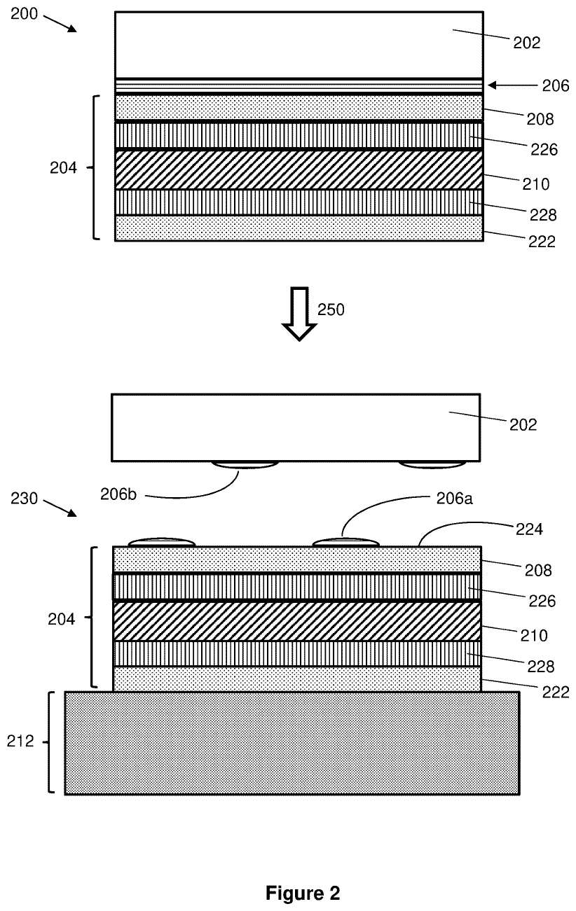

An embodiment of the invention will be described with reference to FIG. 2. Transferrable photovoltaic device arrangement 200 includes flexible release substrate 202 on which thin-film photovoltaic device 204 is located. Thin-film photovoltaic device 200 includes the following functional layers, in sequence: first transparent conductive layer 208 over the flexible release substrate, charge transport layer 226, photoactive layer 210, charge transport layer 228 and second transparent conductive layer 222. Second transparent conductive layer 222 comprises a heat-activatable transparent conductive adhesive, as disclosed herein. Charge transport layer 226 may be an electron-selective transport layer and charge transport layer 228 is a hole-selective transport layer, or vice versa, as required to match the architecture of the bottom sub-cell.

Transferrable photovoltaic device arrangement 200 includes a low-cohesion sacrificial layer 206 which is interposed between flexible release substrate 202 and transparent conductive layer 208. Sacrificial layer 206 includes a heat-activatable adhesive (such as PEO) and optionally a conductive component (such as PEDOT:PSS). When heated, the heat-activatable adhesive fluidises or softens so that the sacrificial layer develops a suitably low cohesion. The sacrificial layer thus forms the interface which is selectively broken when separating flexible release substrate 202 from thin-film photovoltaic device 204, in the adhesion and separation method steps indicated by arrow 250.

In a method of producing a tandem photovoltaic cell, represented by arrow 250, thin-film photovoltaic device 204 is transferred to bottom photovoltaic sub-cell 212, which may be a silicon photovoltaic cell. Thin-film photovoltaic device 204 is thus adhered to bottom sub-cell 212 by (i) bringing second transparent conductive layer 222 into contact with the receipt surface of bottom sub-cell 212 and (ii) heat-activating the transparent conductive adhesive in second transparent conductive layer 222 to induce adhesion. Optionally, this is done by hot-pressing transferrable photovoltaic device arrangement 200 onto bottom photovoltaic sub-cell 212 at a suitable temperature and dwell time to fluidise or soften a heat-activatable adhesive polymer in the transparent conductive adhesive. After the heat-activated adhesion step, thin-film photovoltaic device 204 and bottom photovoltaic sub-cell 212 are functionally coupled via transparent conductive layer 222, which forms a recombination layer or tunnel junction between the top and bottom sub-cells in tandem photovoltaic cell 230.

Transfer method 250 also includes a step of separating flexible release substrate 202 from thin-film photovoltaic device 204. The separation step involves (i) heat-activating the heat-activatable adhesive in sacrificial layer 206 to lower the cohesion thereof, and (ii) peeling off flexible release substrate 202 to progressively break the activated sacrificial layer. Optionally, the heat-activation is done when hot-pressing transferrable photovoltaic device arrangement 200 onto bottom photovoltaic sub-cell 212, so that flexible release substrate 202 is separated near-simultaneously with the adhesion of thin-film photovoltaic device 204 to bottom photovoltaic sub-cell 212. This may be done in a roll lamination process, as described herein with reference to FIG. 6.

Following the separation step, tandem photovoltaic cell 230 has transparent conductive layer 208 at an outer conductive surface 224, through which current can be drawn when tandem photovoltaic cell 230 is in operation. Because sacrificial layer 206 is a very thin layer (and optionally conductive), any residue 206a remaining on transparent conductive layer 208 has an acceptably low impact on the conductivity of outer conductive surface 224.

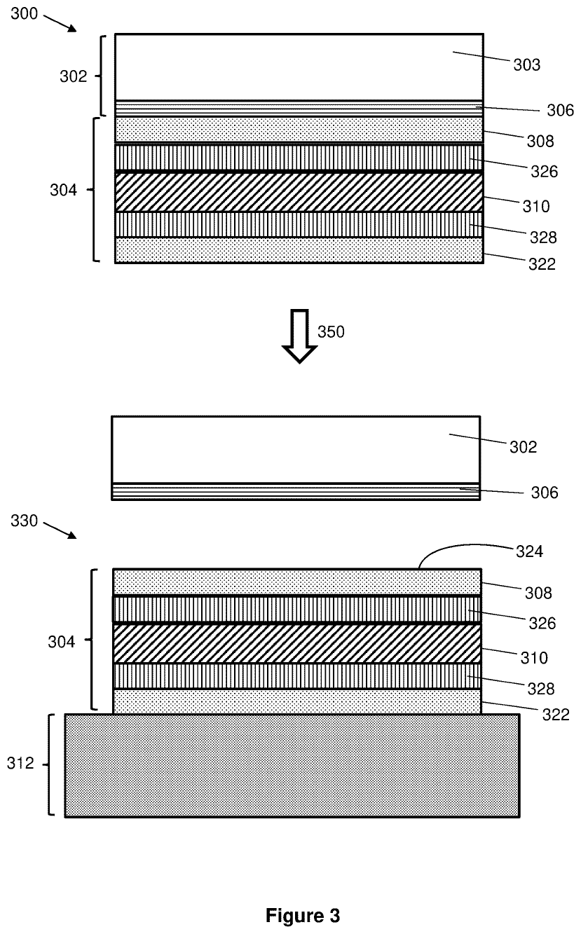

Another embodiment of the invention will be described with reference to FIG. 3. Transferrable photovoltaic device arrangement 300 includes flexible release substrate 302 on which thin-film photovoltaic device 304 is located. Flexible release substrate 302 includes a flexible polymeric film 303 (such as PET) coated with non-stick coating 306 (a low surface energy polymer such as a siloxane polymer). Thin-film photovoltaic device 304 includes the following functional layers, in sequence: first transparent conductive layer 308, charge transport layer 326, photoactive layer 310, charge transport layer 328 and second transparent conductive layer 322. Second transparent conductive layer 322 comprises an activatable transparent conductive adhesive, as disclosed herein.

First transparent conductive layer 308 is in direct contact with non-stick coating 306, thus forming the interface which is selectively broken when separating flexible substrate 302 from thin-film photovoltaic device 304, in the adhesion and separation method steps indicated by arrow 350.

In a method of producing a tandem photovoltaic cell, represented by arrow 350, thin-film photovoltaic device 304 is transferred to bottom photovoltaic sub-cell 312, which may be a silicon photovoltaic cell. Thin-film photovoltaic device 304 is thus adhered to bottom sub-cell 312 by (i) bringing second transparent conductive layer 322 into contact with the receipt surface of bottom sub-cell 312 and (ii) activating the transparent conductive adhesive in second transparent conductive layer 322 to induce adhesion, for example with heat or radiation. Optionally, the activation is performed while pressing transferrable photovoltaic device arrangement 300 onto bottom photovoltaic sub-cell 312.

Transfer method 350 also includes a step of separating flexible release substrate 302 from thin-film photovoltaic device 304. The separation step simply involves peeling off flexible substrate 302 to progressively break the interface between non-stick coating 306 and first transparent conductive layer 308. Flexible substrate 302 may be separated near-simultaneously with the adhesion of thin-film photovoltaic device 304 to bottom photovoltaic sub-cell 312, for example in a roll lamination process, as described herein with reference to FIG. 6.

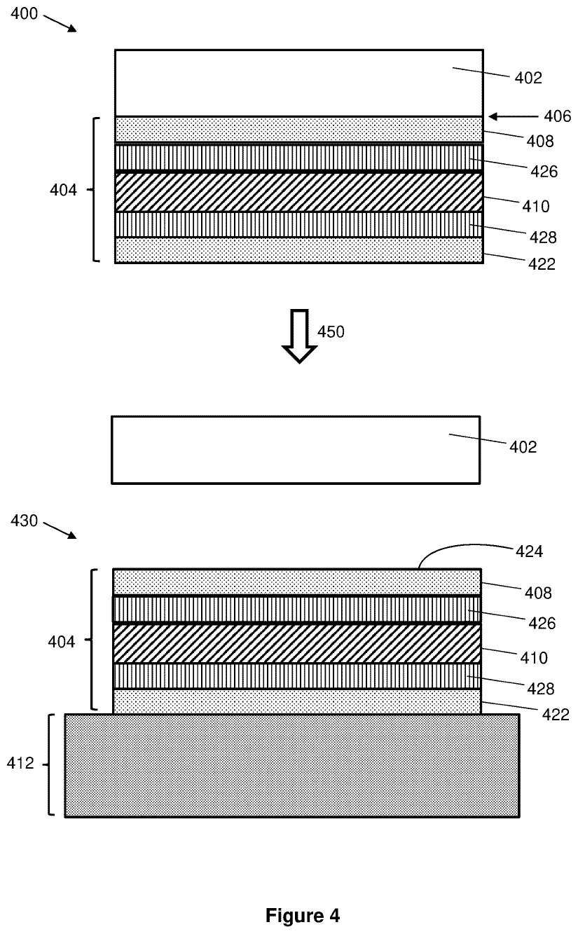

Another embodiment of the invention will be described with reference to FIG. 4. Transferrable photovoltaic device arrangement 400 includes flexible release substrate 402 on which thin-film photovoltaic device 404 is located. Flexible release substrate 402 may be a flexible polymeric film such as PET. Thin-film photovoltaic device 404 includes the following functional layers, in sequence: first transparent conductive layer 408, charge transport layer 426, photoactive layer 410, charge transport layer 428 and second transparent conductive layer 422. Second transparent conductive layer 422 comprises a heat-activatable transparent conductive adhesive, as disclosed herein.

First transparent conductive layer 408 is in direct contact with flexible release substrate 402, thus forming the interface which is selectively broken when separating flexible substrate 402 from thin-film photovoltaic device 404 in the adhesion and separation method steps indicated by arrow 450. First transparent conductive layer 408 includes a heat-activatable adhesive (e.g. a thermoplastic polymer) and a conductive component, which may suitably be a metal, a metal oxide or a conductive polymer or polymer composite (such as PEDOT:PSS).

In a method of producing a tandem photovoltaic cell, represented by arrow 450, thin-film photovoltaic device 404 is transferred to bottom photovoltaic sub-cell 412, which may be a silicon photovoltaic cell. Thin-film photovoltaic device 404 is thus adhered to bottom sub-cell 412 by (i) bringing second transparent conductive layer 422 into contact with the receipt surface of bottom sub-cell 412 and (ii) heat-activating the transparent conductive adhesive in second transparent conductive layer 422 to induce adhesion. Optionally, this is done by hot-pressing transferrable photovoltaic device arrangement 400 onto bottom photovoltaic sub-cell 412 at a suitable temperature and dwell time to fluidise or soften a heat-activatable adhesive polymer in the transparent conductive adhesive.

Transfer method 450 also includes a step of separating flexible release substrate 402 from thin-film photovoltaic device 404. The separation step involves (i) heat-activating the heat-activatable adhesive in first transparent conductive layer 408 to release (de-bond) the flexible release substrate, and (ii) peeling off flexible release substrate 402 to progressively break the interface. Optionally, the heat-activation is done when hot-pressing transferrable photovoltaic device arrangement 400 onto bottom photovoltaic sub-cell 412, so that flexible release substrate 402 is separated near-simultaneously with the adhesion of thin-film photovoltaic device 404 to bottom photovoltaic sub-cell 412. This may be done in a roll lamination process, as described herein with reference to FIG. 6.

### EXAMPLES

The present invention is described with reference to the following examples. It is to be understood that the examples are illustrative of and not limiting to the invention described herein.

### Materials and Procedures.

A custom-built roll-to-roll slot die coating machine with a slot die head with 50 μm shim was used to fabricate solution-processed films. The machine was designed to handle narrow (25 mm width) films with a minimum material usage for research purposes. Sheet resistances of films were tested using a Jandel RM3000 four-point probe system.

### Example 1. Transferable Photovoltaic Device on a Non-Stick Surface

A transparent conductive layer was produced by applying a commercial aqueous 1% PEDOT:PSS solution (S315, Agfa) by roll-to-roll slot die coating onto a roll of 25 mm wide, 50 micron thick PET film coated with a non-stick silicone release layer (FRA 319, Fox River). Aqueous solutions, including aqueous PEDOT:PSS solutions, are susceptible to dewetting on a non-stick low-surface energy surface, in which case a continuous layer will not be formed. Therefore, the PEDOT:PSS solution was deposited onto the substrate on a heated stage (80° C.) which mitigates the dewetting issue by lowering the surface tension of the solution and accelerating solvent evaporation. An air blade (10 L/min) was also engaged to promote solvent evaporation before dewetting occurs. The PEDOT:PSS solution was deposited in a 13 mm wide continuous strip at a loading of 3.8 μl/cm² (wet film thickness thus about 38 microns) at 0.3 m/min speed and dried at 130° C. for 30 sec.

An electron transport layer was then produced on the first transparent conductive layer by applying a commercial ZnO solution (2.8% in 2-propanol, InfityPV) by roll-to-roll slot die coating on the dried PEDOT:PSS film. The ZnO solution was deposited in a 13 mm wide continuous strip over the PEDOT:PSS strip at a loading of 0.5 μl/cm² (wet film thickness thus about 5 microns) at 0.3 m/min speed and dried at 130° C. for 30 sec.

A photoactive layer was then produced on the electron transport layer by applying a solution consisting of 8 mg of PBF-QxF and 12 mg of Y6 per 1 ml of dichlorobenzene by roll-to-roll slot die coating. The solution was deposited in a 7 mm wide continuous strip over the ZnO strip while the substrate was on a heated stage (130° C.), at a loading of 2 μl/cm² (wet film thickness thus about 20 microns, dry film thickness about 260 nm) at 0.3 m/min speed.

The separability of the multi-layered photovoltaic device, comprising the transparent conductive layer, electron transport layer and photoactive layer, from the release substrate was investigated by a simple tape peeling test (also known as a Scotch tape test). It was observed that the device detached selectively at the interface between the transparent conductive layer and the non-stick coating of the release layer, so that the multi-layered photovoltaic device was transferred intact to the tape.

### Example 2. Transferable Photovoltaic Device with a Sacrificial Layer

A coating composition for preparing a sacrificial layer was prepared by mixing 10 ml of commercial aqueous 1.3-1.7% PEDOT:PSS solution (Clevios Al 4083, Heraeus), 200 mg of polyethylene oxide (PEO), a water-soluble low-melting point polymer (molecular weight 100 000 Daltons, melting point 65° C.), and 10 ml of 2-propanol. A sacrificial layer was produced by applying this mixture by roll-to-roll slot die coating onto a roll of uncoated polyethylene terephthalate (PET) film. The mixture was deposited in a 25 mm wide continuous strip at a loading of 1 μl/cm² (wet film thickness thus about 10 microns) of the solution at room temperature and then dried at 130° C. for 30 sec. The dried film, which was non-tacky at room temperature, became soft and tacky when heated above 80° C. In a Scotch tape test, the tape was firmly adhered at room temperature but peeled off easily when heated to 80° C. Based on visual inspection, the sacrificial layer remained present on the PET film following detachment.

A transparent conductive layer was then produced by applying a commercial aqueous 1% PEDOT:PSS solution (S315, Agfa) by roll-to-roll slot die coating onto the sacrificial layer. The PEDOT:PSS solution was deposited in a 13 mm wide continuous strip at a loading of 3.8 μl/cm² (wet film thickness thus about 38 microns) at 0.3 m/min speed and dried at 130° C. for 30 sec. The sheet resistance of the transparent conductive layer was about 80 ohm/sq.

A photoactive layer was then produced on the transparent conductive layer by applying a solution consisting of 8 mg of PBF-QxF and 12 mg of Y6 per 1 ml of dichlorobenzene by roll-to-roll slot die coating. The solution was deposited in a 7 mm wide continuous strip over the PEDOT:PSS strip while the substrate was on a heated stage (130° C.) at a loading of 2 μl/cm² (wet film thickness thus about 20 microns, dry film thickness about 260 nm) at 0.3 m/min speed.

The separability of the multi-layered photovoltaic device, comprising the transparent conductive layer and photoactive layer, from the release substrate was investigated by a Scotch tape test at 80° C. The device detached readily from the PET substrate via breakage of the heat-activated sacrificial layer. The sheet resistance of the transparent conductive layer, as exposed after removal of the PET film, was about 90-100 ohm/sq.

PEDOT:PSS was included in the sacrificial layer for several reasons. Firstly, it overcame the problem of dewetting encountered when roll-to-roll slot die coating a solution of PEO only. Secondly, the inclusion of the conductive PEDOT:PSS is believed to mitigate the effects of sacrificial layer residue on the conductivity of the transparent conductive layer.

### Example 3. Transfer of Photovoltaic Device by Adhesion with a Transparent Conductive Adhesive and Removal of the Release Substrate

A coating composition for preparing a separation enabling sacrificial layer was prepared by dissolving 2 g of ethylene vinyl acetate in 40 ml of xylene by stirring at 50° C. for 30 min. A sacrificial layer was produced by applying this solution by roll-to-roll slot die coating onto a roll of uncoated polyethylene terephthalate (PET) film. The mixture was deposited in a 25 mm wide continuous strip at a loading of 0.8 μl/cm² (wet film thickness thus about 8 microns) of the solution at 90° C. and then dried by 80° C. hot air blowing for 30 sec. The dried film, which was non-tacky at room temperature, became soft and tacky when heated above 90° C.

A transparent conductive layer was then produced by applying a commercial aqueous 1% PEDOT:PSS solution (S315, Agfa) by roll-to-roll slot die coating onto the sacrificial layer. The PEDOT:PSS solution was deposited with 13 mm width on the 25 mm wide PET film at a loading of 3.3 μl/cm² (wet film thickness thus about 33 microns) at 0.3 m/min speed and dried at 90° C. for 2 min. The relatively low drying temperature was chosen to avoid melting the sacrificial layer before the conductive layer is solidified.

An electron transport layer was then produced by applying a commercial ZnO nanoparticle solution (InfinityPV, 2.8 wt % in 2-propanol) by roll-to-roll slot die coating onto the transparent conductive layer at a loading of 0.58 μl/cm² (wet film thickness thus about 5.8 microns) at 0.2 m/min speed. The film was then dried by 90° C. hot air blowing for 2 min.

A coating composition for preparing a perovskite photoactive layer was prepared by mixing 21.5 mg of formamidinium iodide, 139.1 mg of methylammonium iodide, 5.6 mg of methylammonium bromide, 507 mg of lead iodide and 1 ml of acetonitrile. Methylamine gas was bubbled until the solution became clear. The perovskite precursor solution was then applied by roll-to-roll slot die coating onto the electron transport layer at a loading of 0.58 μl/cm² (wet film thickness thus about 5.8 microns) at 0.6 m/min speed.

The resultant transferrable photovoltaic device arrangement 700, as schematically depicted in FIG. 7, comprises PET flexible release substrate 702, heat-activatable low-cohesion sacrificial layer 704, PEDOT:PSS transparent conductive layer 706, ZnO electron transport layer 708 and perovskite photoactive layer 710.

Transferrable photovoltaic device arrangement 700 was then used to transfer a thin-film photovoltaic device to a conductive substrate (Solutia OC50 substrate), comprising PET film 712 coated with a layer of indium tin oxide (ITO) 714, by the following method (method 701 schematically depicted in FIG. 7). A transparent conductive adhesive (3M, Electrically Conductive Adhesive Transfer Tape) layer 716 (25 mm width) was applied by manual lamination to ITO layer 714. The ITO-coated PET film was then placed on a hot stage (110° C.) and transferrable photovoltaic device arrangement 700 was manually laminated thereto such that perovskite photoactive layer 710 adhered to ITO layer 714 via transparent conductive adhesive layer 716. Immediately thereafter, PET flexible release substrate 702 was peeled away, leaving the thin-film photovoltaic device comprising layers 706, 708 and 710 adhered to the conductive substrate by transparent conductive interlayer 716, with PEDOT:PSS transparent conductive layer 706 exposed at the outer surface. The thin-film photovoltaic device detached cleanly from the PET flexible release substrate 702 via breakage of heat-activated sacrificial layer 704.

Those skilled in the art will appreciate that the invention described herein is susceptible to variations and modifications other than those specifically described. It is understood that the invention includes all such variations and modifications which fall within the spirit and scope of the present invention.

1.-32. (canceled)

33. A transferrable photovoltaic device arrangement for transferring a thin-film photovoltaic device to a bottom photovoltaic sub-cell to produce a tandem photovoltaic cell, the transferrable photovoltaic device arrangement comprising:
a flexible release substrate; and
a thin-film photovoltaic device comprising (i) a first transparent conductive layer located over the flexible release substrate and (ii) a photoactive layer located over the first transparent conductive layer,
wherein the first transparent conductive layer is a solution-processed layer comprising at least one selected from a conductive polymer or polymer composite, an activatable adhesive, and an organic binder, and
wherein the flexible release substrate is separable from the thin-film photovoltaic device after the thin-film photovoltaic device is adhered to the bottom photovoltaic sub-cell with a transparent conductive adhesive, thereby exposing the first transparent conductive layer at an outer conductive surface of the thin-film photovoltaic device.

34. The transferrable photovoltaic device arrangement according to claim 33, wherein the first transparent conductive layer comprises a first activatable adhesive, wherein the flexible release substrate is separable from the thin-film photovoltaic device when the first activatable adhesive is activated.

35. The transferrable photovoltaic device arrangement according to claim 34, wherein the first activatable adhesive is a heat-activatable adhesive polymer.

36. The transferrable photovoltaic device arrangement according to claim 33, wherein the flexible release substrate comprises a non-stick surface, wherein the flexible release substrate is separable from the thin-film photovoltaic device by delaminating the first transparent conductive layer from the non-stick surface.

37. The transferrable photovoltaic device arrangement according to claim 36, wherein the non-stick surface is a surface of a non-stick coating on the flexible release substrate.

38. The transferrable photovoltaic device arrangement according to claim 33, comprising a low-cohesion sacrificial layer interposed between the flexible release substrate and the first transparent conductive layer, wherein the low-cohesion sacrificial layer has intrinsically low cohesion or has low cohesion when activated such that the flexible release substrate is separable from the thin-film photovoltaic device by breaking the low-cohesion sacrificial layer.

39. The transferrable photovoltaic device arrangement according to claim 33, wherein the thin-film photovoltaic device further comprises (iii) a second transparent conductive layer, located over the photoactive layer, wherein the second transparent conductive layer comprises the transparent conductive adhesive for adhering the thin-film photovoltaic device to the bottom photovoltaic sub-cell.

40. The transferrable photovoltaic device arrangement according to claim 39, wherein the transparent conductive adhesive comprises a second activatable adhesive, wherein the second transparent conductive layer is adherent to the bottom photovoltaic sub-cell when the second activatable adhesive is activated.

41. The transferrable photovoltaic device arrangement according to claim 33, wherein the photoactive layer is a photoactive perovskite layer.

42. The transferrable photovoltaic device arrangement according to claim 33, configured as a roll for a roll lamination process in which the thin-film photovoltaic device is pressed onto the bottom photovoltaic sub-cell and the flexible release substrate is separated from the thin-film photovoltaic device.

43. A tandem photovoltaic cell arrangement comprising a bottom photovoltaic sub-cell and a transferrable photovoltaic device arrangement according to claim 33, wherein the thin-film photovoltaic device is adhered to the bottom photovoltaic sub-cell via a second transparent conductive layer comprising a transparent conductive adhesive.

44. A method of producing a transferrable photovoltaic device arrangement, the method comprising:
providing a flexible release substrate; and
producing a thin-film photovoltaic device on the flexible release substrate by successively forming (i) a first transparent conductive layer over the flexible release substrate; and (ii) a photoactive layer over the first transparent conductive layer,
wherein the first transparent conductive layer is formed by solution-processing and comprises at least one selected from a conductive polymer or polymer composite, an activatable adhesive, and an organic binder, and
wherein the flexible release substrate is separable from the thin-film photovoltaic device to expose the first transparent conductive layer at an outer conductive surface of the thin-film photovoltaic device.

45. The method according to claim 44, wherein forming the first transparent conductive layer over the flexible release substrate comprises applying a first fluid composition, comprising a first conductive component or reactive precursor thereof, to form a wet film over the flexible release substrate; and solidifying the wet film to form the first transparent conductive layer over the flexible release substrate.

46. The method according to claim 44, wherein the first fluid composition comprises a first activatable adhesive.

47. The method according to claim 46, wherein the first activatable adhesive is a heat-activatable adhesive polymer, wherein the flexible release substrate is separable from the thin-film photovoltaic device when the first transparent conductive layer is heated.

48. The method according to claim 44, wherein the flexible release substrate comprises a non-stick surface and the first transparent conductive layer is formed directly on the non-stick surface.

49. The method according to claim 44, wherein the flexible release substrate comprises a low-cohesion sacrificial layer on its surface and the first transparent conductive layer is formed directly on the low-cohesion sacrificial layer.

50. The method according to claim 44, wherein the flexible release substrate is configured as a roll and the thin-film photovoltaic device is produced on the flexible release substrate by coating and/or printing steps in a roll-to-roll process.

51. A method of producing a tandem photovoltaic cell, comprising:
providing a transferrable photovoltaic device arrangement according to claim 33, or as produced by the method;
adhering the thin-film photovoltaic device of the transferrable photovoltaic device arrangement to a bottom photovoltaic sub-cell with a transparent conductive adhesive, thereby coupling the thin-film photovoltaic device and the bottom photovoltaic sub-cell via a second transparent conductive layer; and
separating the flexible release substrate of the transferrable photovoltaic device arrangement from the thin-film photovoltaic device, thereby producing a tandem photovoltaic cell having the first transparent conductive layer of the thin-film photovoltaic device at an outer conductive surface.

52. The method according to claim 51, wherein the bottom photovoltaic sub-cell is a silicon photovoltaic cell.

53. The method according to claim 51, wherein the transferrable photovoltaic device arrangement is configured as a roll, and wherein the thin-film photovoltaic device is adhered to the bottom photovoltaic sub-cell and the flexible release substrate is separated from the thin-film photovoltaic device in a roll lamination process.
